(19) United States
(12) Patent Application Publication
(10) Pub. No.: US 2024/0395785 A1
(43) Pub. Date: Nov. 28, 2024

(54) METHOD OF FABRICATING A WAFER STACK AND WAFER STACK PRODUCED THEREBY

(71) Applicant: Taiwan Semiconductor Manufacturing Company LTD, Hsinchu (TW)

(72) Inventors: Ming-Hsien Yang, Taichung City (TW); Chun-Hao Chou, Tainan City (TW); Chia-Yu Wei, Tainan City (TW); Kuo-Cheng Lee, Tainan City (TW); Chung-Liang Cheng, Changhua (TW); Sheng-Chau Chen, Tainan City (TW)

(21) Appl. No.: 18/200,886

(22) Filed: May 23, 2023

(51) Int. Cl. H01L 25/16; H01L 23/00; H01L 27/146

(52) U.S. Cl. CPC H01L 25/167; H01L 24/08; H01L 24/80; H01L 27/14634; H01L 2224/08145; H01L 2224/80895; H01L 2224/80896

(57) ABSTRACT

A method and wafer stack that includes a first wafer component, a second wafer component, and third wafer component. The first wafer component includes a frontside and a backside. The wafer stack also includes a second wafer component having a frontside and a backside, such that the frontside of the second wafer component is bonded to the frontside of the first wafer component. In addition, the wafer stack includes a third wafer component having a frontside and a backside, such that the frontside of the third wafer component is bonded to the backside of the second wafer component. The first wafer component includes a composite metal grid array with one or more photodiodes formed on the backside.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer.

As semiconductor technologies further advance, stacked semiconductor devices, e.g., three dimensional integrated circuits, have emerged to further reduce the physical size of semiconductor devices. In a stacked semiconductor device, various circuits are fabricated on different semiconductor wafers. Semiconductor wafers may then be stacked on top of one another for smaller form factors of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a CMOS image sensor device wafer stack in accordance with a first embodiment.

FIGS. 2A-2M is a simplified a cross-sectional view of the process flow of fabricating the CMOS image sensor device wafer stack in accordance with some embodiments.

FIGS. 3A-3I is a simplified cross-sectional flow process of forming planar transistors in accordance with one example embodiment.

FIG. 4 is a cross-sectional view of a CMOS image sensor device wafer stack in accordance with a second embodiment.

FIGS. 5A-5I is a simplified cross-sectional flow process of forming a three-dimensional transistor used in the second embodiment of FIG. 4.

FIGS. 6A-6B are simplified cross-sectional and top views of the three-dimensional transistor used in the second embodiment of FIG. 4.

FIG. 7 is a cross-sectional view of a CMOS image sensor device wafer stack in accordance with a third embodiment.

FIGS. 8A-8I is a simplified cross-sectional flow process of forming a three-dimensional transistor used in the third embodiment of FIG. 7.

FIGS. 9A-9B are simplified cross-sectional and top views of the three-dimensional transistor used in the third embodiment of FIG. 7.

FIG. 10 is a cross-sectional view of a CMOS image sensor device wafer stack in accordance with a fourth embodiment.

FIG. 11 a simplified cross-sectional view of a 1T1C component used in the fourth embodiment of FIG. 10.

FIG. 12 is a cross-sectional view of a CMOS image sensor device wafer stack in accordance with a fifth embodiment

FIG. 13 a simplified cross-sectional view of a 1T1C component used in the fifth embodiment of FIG. 12.

FIG. 14 is a cross-sectional view of a CMOS image sensor device wafer stack in accordance with a sixth embodiment.

FIG. 15 a simplified cross-sectional view of a 1T1C component used in the sixth embodiment of FIG. 14.

FIG. 16A is an illustration of pixel-level hybrid bonding (PLHB) of the wafer stack in accordance with some embodiments.

FIG. 16B is an illustration of column-level hybrid bonding (CLHB) of the wafer stack in accordance with some embodiments.

FIG. 17A-17C is an illustration of hybrid bond types used in the wafer stack in accordance with some embodiments.

FIG. 18A is an illustration of PLHB bonding using one of the hybrid bond types of FIGS. 17A-17C in accordance with some embodiments.

FIG. 18B is an illustration of PLHB bonding using another of the hybrid bond types of FIGS. 17A-17C in accordance with some embodiments.

FIG. 19 is an illustration of various configurations of PLHB and CLHB wafer stack bonding in accordance with some embodiments.

FIG. 20 is a flowchart illustrating a method for fabricating a wafer stack in accordance with one embodiment.

FIG. 21 is a flowchart illustrating a method for fabricating a wafer stack in accordance with one embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

As semiconductor technologies further advance, stacked semiconductor devices have emerged as an effective alternative to further reduce the physical size of a semiconductor device. In a stacked semiconductor device, active circuits such as logic, memory, processor circuits and the like are fabricated on different semiconductor wafers. Two or more semiconductor wafers may be installed on top of one another to further reduce the form factor of the semiconductor device.

Two semiconductor wafers may be bonded together through suitable bonding techniques. Suitable bonding techniques may include, for example and without limitation, direct bonding, chemically activated bonding, plasma activated bonding, anodic bonding, eutectic bonding, glass frit bonding, adhesive bonding, thermo-compressive bonding, reactive bonding, hybrid bonding, and the like. Once two semiconductor wafers are bonded together, the interface between two semiconductor wafers may provide an electrically conductive path between the stacked semiconductor wafers.

One advantageous feature of stacked semiconductor devices is much higher density can be achieved by employing stacked semiconductor devices. Furthermore, stacked semiconductor devices can achieve smaller form factors, cost-effectiveness, increased performance and lower power consumption. For example, a complementary metal-oxide-semiconductor (CMOS) image sensor (CIS) device may include a plurality of pixel regions arranged on or within a substrate. Each pixel region comprises an image sensing element, such as a photodiode, that is configured to receive incident light comprising photons. The pixel regions may be separated from one another by a deep trench isolation (DTI) structure to improve the quantum efficiency of the CIS. Such a CIS may utilize one System on Chip (SOC) wafer stacked on one Application Specific Integrated Circuit (ASIC) wafer. As sophistication increases, and more is required of CIS devices, additional features are added. In accordance with some embodiments disclosed herein, there is provided a CIS device utilizing three or more stacked wafer components, providing, among other advantages, increased processing capacity, data storage (i.e., memory), and the like. In such embodiments, the CIS device may utilize, for example, one SOC wafer and two ASIC wafers or two SOC wafers and one ASIC wafer bonding. Further, each wafer may include Metal-Insulator-Metal (MIM) as capacitors and control nodes to form a one transistor/one capacitor component, i.e., 1T1C. According to one embodiment, the middle wafer may include front side and back side transistor arrays by using a silicon on insulator (SOI) substrate. In one embodiment, such a backside transistor array may comprise a vertical 3D transistor array (three-dimensional thin film transistor of indium-gallium-zinc-oxygen InGaZnO (3D TFT IGZO) with a FinFET structure) for backend bias and current drive.

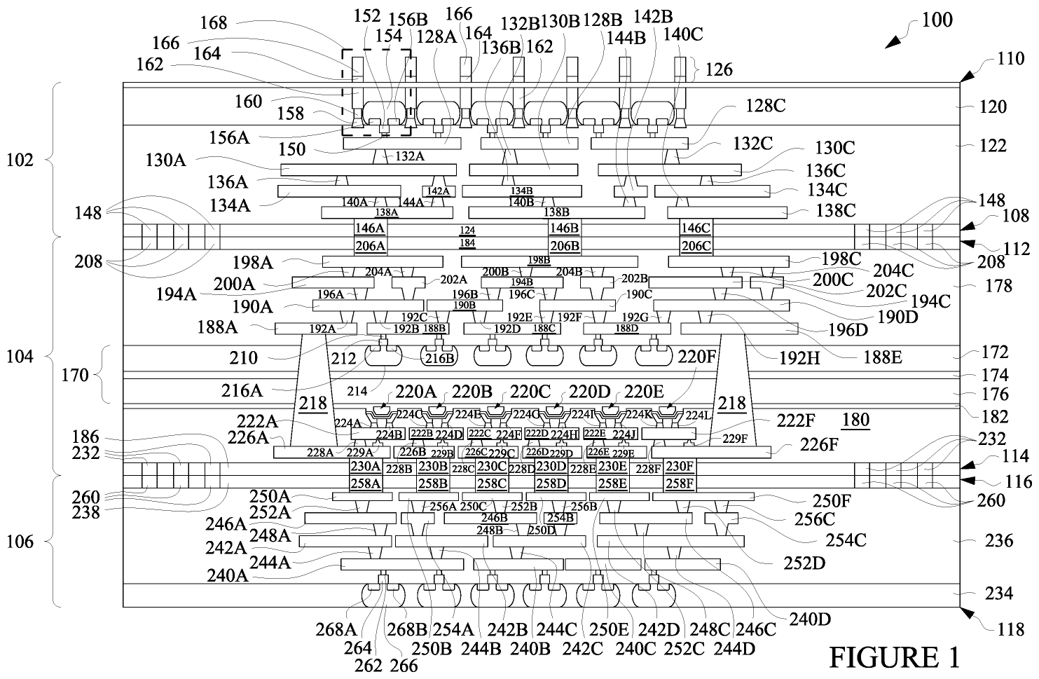

Turning now to FIG. 1, there is provided a cross-sectional view of a CIS device wafer stack 100 in accordance with one embodiment of the subject disclosure. As shown in FIG. 1, the CIS device wafer stack 100 comprises a first SOC wafer component 102, a first ASIC wafer component 104, and a second ASIC wafer component 106. It will be appreciated that the CIS device wafer stack 100 is a representative, non-limiting example of one possible implementation of the systems and methods described herein. As illustrated in FIG. 1, the first SOC wafer component 102 includes a first SOC wafer frontside 108 and a first SOC wafer backside 110. The first ASIC wafer component 104 includes a first ASIC wafer frontside 112 and first ASIC wafer backside 114. Similarly, the second ASIC wafer component 106 includes a second ASIC wafer frontside 116 and a second ASIC wafer backside 118. In the embodiment of FIG. 1, the first SOC wafer frontside 108 is bonded to the first ASIC wafer frontside 112, and the first ASIC wafer backside 114 is bonded to the second ASIC wafer frontside 116. Variations on the wafer stacking i.e., frontside/backside bonding, as illustrated in FIG. 1 are contemplated herein and the illustration of the ordering in FIG. 1 is intended solely as one example of such order of wafer stacking in accordance with some embodiments. Furthermore, it will be appreciated that the wafer stack 100 may include a single ASIC wafer component and two SOC wafer components, three SOC wafer components, three ASIC wafer components, or four or more wafer components utilizing the connectivity, layout, features, and bonds, as described herein.

According to some embodiments, the first ASIC wafer component 104, described in greater detail below, may include, for example and without limitation, logic circuitry, ADC (analog-to-digital converter), ISP (image signal processor), and the like. The second ASIC wafer component 106, described in greater detail below, may include, for example and without limitation, logic circuits, ISP (image signal processor), ADC (analog-to-digital converter), and the like.

In the example embodiment depicted in FIG. 1, the first SOC wafer component 102 includes an SOC substrate 120, a dielectric layer 122, and an anchor layer 124. In some embodiments, the SOC substrate 120 may be implemented as a semiconducting material. Such materials can include silicon, for example and without limitation, in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the SOC substrate 120 is silicon.

As illustrated in FIG. 1, the dielectric layer 122 may comprise an insulating material, such as silicon dioxide (SiO₂) or silicon nitride (SiN), silicon oxynitride (SiON), fluoride-doped silicate glass, or other dielectric material. The aforementioned anchor layer 124 may be implemented as a suitable dielectric material including, for example and without limitation SiN, oxide, SiOₓF_{y}C_{z}Nₐ, polymer, resin, low-K material, high-K material, or any related insulation layers, as will be appreciated. In some embodiments, the dielectric layer 122 and the anchor layer 124 may be implemented as the same or different materials.

The dielectric layer 122 of the SOC wafer component 102 is depicted in FIG. 1 as including one or more first metal layer components 128A, 128B, 128C. Disposed in the dielectric layer 122 are one or more second metal layer components 130A, 130B, 130C, electrically connected to respective first metal layer components 128A, 128B, 128C by respective first vias 132A, 132B, 132C. It will be appreciated that such first vias 132A-132C may be fabricated of suitable conductive materials including, for example and without limitation, copper, copper-alloy, aluminum, aluminum-alloy, and the like. The SOC wafer component 102 further includes one or more third metal layer components 134A, 134B, 134C disposed in the dielectric layer 122 and electrically connected to respective one or more second metal layer components 130A, 130B, 130C by respective second vias 136A, 136B, 136C. It will be appreciated that such second vias 136A-136C may be fabricated of suitable conductive materials including, for example and without limitation, copper, copper-alloy, aluminum, aluminum-alloy, and the like. The one or more third metal layer components 134A, 134B, 134C are connected to respective one or more top metal layer components 138A, 138B, 138C by respective third vias 140A, 140B, 140C. In accordance with some embodiments, the third vias 140A-140C may be fabricated of suitable conductive materials including, for example and without limitation, copper, copper-alloy, aluminum, aluminum-alloy, metal, metal alloy, or the like.

The one more top metal layer components 138A, 138B, 138C are illustrated in FIG. 1 as being electrically connected via respective fourth vias 144A, 144B, and 144C to suitable metal-insulator-metal (MiM) components 142A, 142B, 142C, which are respectively coupled to the second metal layer components 130A, 130B, 130C. In some embodiments, a redistribution layer (RDL) component 146A, 146B, 146C is electrically connected to respective top metal components 138A, 138B, 138C, the RDL components 146A-146C extending through the SOC anchor layer 124, as shown in FIG. 1. In some embodiments, the metal layer components 128A-128C, 130A-130C, 134A-134C, and 138A-138C may be fabricated of copper, copper alloys, aluminum, aluminum-alloy, or other conductive material.

As illustrated in FIG. 1, the SOC wafer component 102 includes one or more anchor pads 148 positioned in or on the anchor layer 124 on the frontside 108. The anchor pads 148 may be implemented as, for example and without limitation, copper, copper-alloy, aluminum, aluminum-alloy, metal, metal alloy, etc., configured to provide one or more connection or attachment points between the SOC wafer component 102 and/or the first ASIC wafer component 104.

The backside 110 of the first SOC wafer component 102, i.e., the side of the SOC substrate 120 depicted as the top of the CIS device wafer stack 100 includes a composite metal grid 126 extending perpendicularly from the SOC substrate 120. The backside 110 of the SOC wafer component 102 may include a variety of components, as will be appreciated. In the exemplary embodiment of FIG. 1, the SOC wafer component 102 includes one or more photodiodes 168. In particular, each photodiode 168, denoted generally by the box on the backside 110 of the SOC wafer component 102 includes a contact 150 electrically coupling the photodiode 168 to a first metal layer component 128A-128C. The contact 150 is coupled to polygate 152, mixed implants 154, a drain 156A, and a source 156B, as shown in FIG. 1. In addition, the photodiode 168 may include an STI 158, a boron IMP 160, a backside deep trench isolation (BDTI) component 162, and a portion of the composite metal grid 126. As illustrated in FIG. 1, the composite metal grid 126 includes a lower grid component 164 and an upper grid component 166. According to some embodiments, the lower grid component 164 may be implemented as, for example and without limitation, a tungsten component, and the upper grid component 166 may be implemented as, for example and without limitation, an oxide component.

The first ASIC wafer component 104 depicted in FIG. 1 includes a first ASIC wafer substrate 170 comprising one or more layers. In the example embodiment of FIG. 1, the substrate 170 comprises a frontside layer 172, a silicon-on-insulator (SOI) layer 174, and a backside layer 176. According to some embodiments, the frontside layer 172 and the backside layer 176 may comprise, for example and without limitation, non-low-k dielectric materials such as silicon oxide, silicon carbide (SiC), silicon carbo-nitride (SiCN), silicon oxy-carbo-nitride (SiOCN), or the like. In the illustration of FIG. 1, the SOI layer 174 may comprise, for example and without limitation silicon oxide, or other suitable insulative material. As shown in FIG. 1, the first ASIC wafer component 104 may be implemented with components, i.e., functionality, formed on both the frontside 112 and the backside 114 of the component 104. That is, fabrication of components may be built upon the frontside layer 172 and the backside layer 176 of the substrate 170, with components formed thereon electrically connected between the frontside 112 and backside 114 using Big Through Silicon Vias (BTSV) 218, i.e., large through-silicon-vias that extend through the entire substrate 170 (e.g., frontside layer 172, SOI layer 174 and backside layer 176), enabling connectivity of components disposed in the frontside layer 172 with components disposed in the backside layer 176, as illustrated in FIG. 1. It will be appreciated that such BTSVs 218 may be fabricated of suitable conductive materials including, for example and without limitation, copper, copper-alloy, aluminum, aluminum-alloy, and the like.

The frontside 112 of the first ASIC wafer component 104 further includes a frontside dielectric layer 178 formed on the frontside layer 172 of the substrate 170. The backside 114 of the first ASIC wafer component 104 includes a backside dielectric layer 180 disposed on the backside layer 176 of the substrate 170. An oxide layer 182 may be formed on the backside layer 176 of the substrate 170, as illustrated in FIG. 1. In some embodiments, the oxide layer 182 may comprise, for example and without limitation, an aluminum-oxide layer (e.g., Al₂O₃), or the like. The first ASIC wafer component 104 may further include a frontside anchor layer 184 formed on the frontside dielectric layer 178 and a backside anchor layer 186 formed on the backside dielectric layer 180. The aforementioned anchor layers 184-186 may be implemented as a suitable dielectric material including, for example and without limitation SiN, oxide, SiOₓF_{y}C_{z}Nₐ, polymer, resin, low-K material, high-K material, or any related insulation layers, as will be appreciated.

The frontside dielectric layer 178 of the first ASIC wafer component 104 is depicted in FIG. 1 as including one or more first metal layer components 188A, 188B, 188C, 188D, and 188E. The first ASIC wafer component 104 further includes one or more second metal layer components 190A, 190B, 190C, and 190D, disposed in the frontside dielectric layer 178, and electrically connected to respective first metal layer components 188A, 188B, 188C 188D, 188E by first vias 192A, 192B, 192C, 192D, 192E, 192F, 192G. It will be appreciated that such first vias 192A-192G may be fabricated of suitable conductive materials including, for example and without limitation, copper, copper-alloy, aluminum, aluminum-alloy, and the like. The first ASIC wafer component 104 further includes one or more third metal layer components 194A, 194B, 194C disposed in the frontside dielectric layer 178 and electrically connected to respective one or more second metal layer components 190A, 190B, 190C, 190D by respective second vias 196A, 196B, 196C, 196D. It will be appreciated that such second vias 196A-196D may be fabricated of suitable conductive materials including, for example and without limitation, copper, copper-alloy, aluminum, aluminum-alloy, and the like. The one or more third metal layer components 194A, 194B, 194C are electrically connected to respective one or more top metal layer components 198A, 198B, 198C by respective third vias 200A, 200B, 200C. It will be appreciated that such third vias 200A-200C may be fabricated of suitable conductive materials including, for example and without limitation, copper, copper-alloy, aluminum, aluminum-alloy, and the like. In some embodiments, the aforementioned metal layer components 188A-188E, 190A-190D, and 194A-194C may be fabricated of copper, copper alloys, aluminum, aluminum-alloy, or other conductive material.

The one more top metal layer components 198A, 198B, 198C are illustrated in FIG. 1 as being electrically connected via respective fourth vias 204A, 204B, and 204C to suitable metal-insulator-metal (MiM) components 202A, 202B, 202C, which are respectively coupled to the second metal layer components 190A, 190C, and 190D. In some embodiments, a redistribution layer (RDL) component 206A, 206B, 206C is electrically connected to respective top metal components 198A, 198B, 198C, the RDL components 206A-206C extending through the frontside anchor layer 184, as shown in FIG. 1. As illustrated in FIG. 1, the first ASIC wafer component 104 includes one or more anchor pads 208 positioned in or on the frontside anchor layer 184.

In addition, the frontside 112 of the first ASIC wafer component 104 may include one or more transistor gates or “devices”, i.e., FinFET device, GAA device, HKMG device, SiGe S/D device, SOI device, Poly device, Doped Poly device, etc., comprising a contact 210 coupling a gate component 212 to a first metal layer component 188B-188D, as shown in FIG. 1. These “devices” may be formed on or in the frontside layer 172 of the first ASIC wafer substrate 170. As further illustrated in FIG. 1, such “devices” may include the gate component 212, mixed implants 214, a drain 216A, and a source 216B, as will be appreciated.

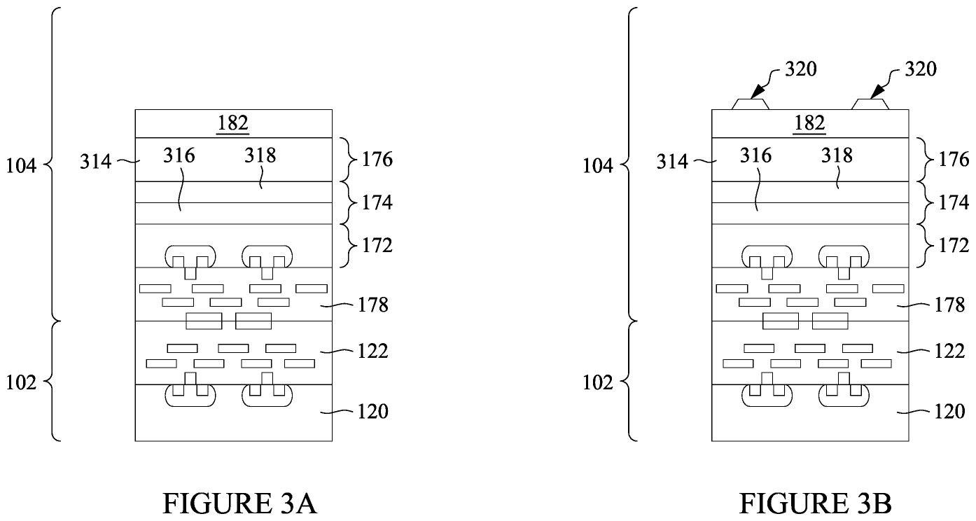

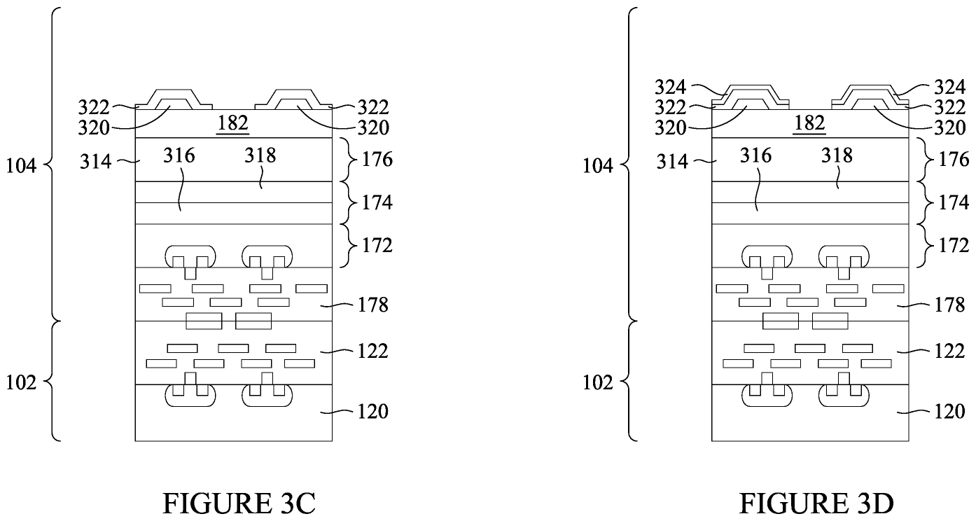

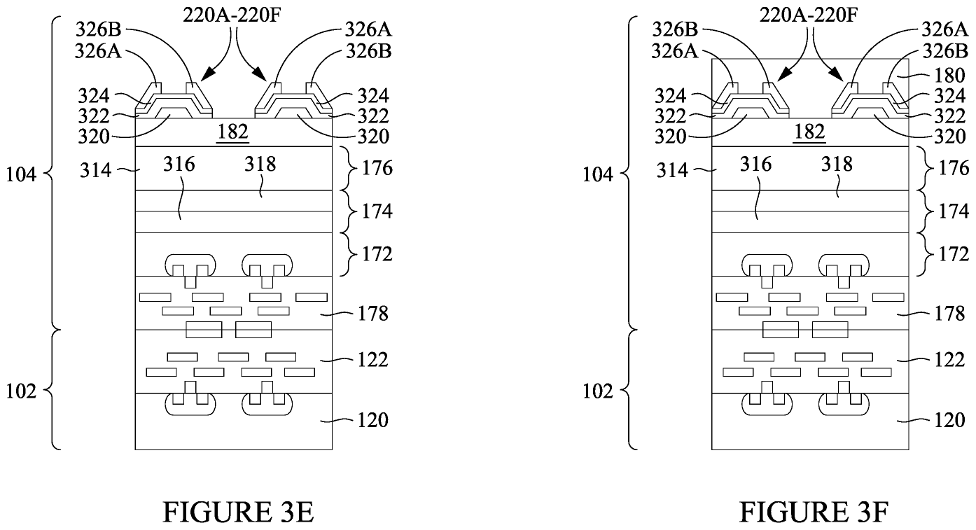

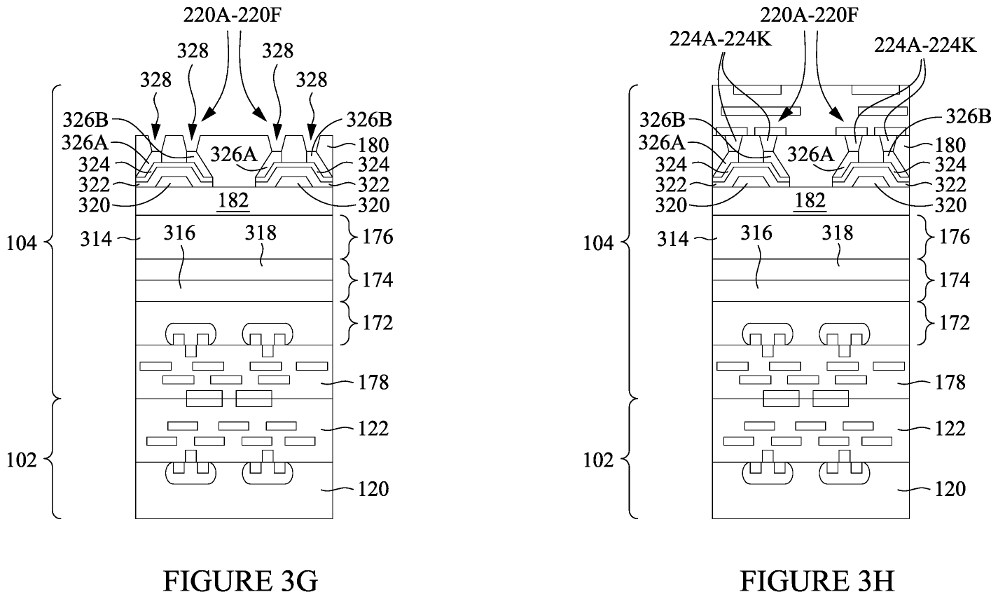

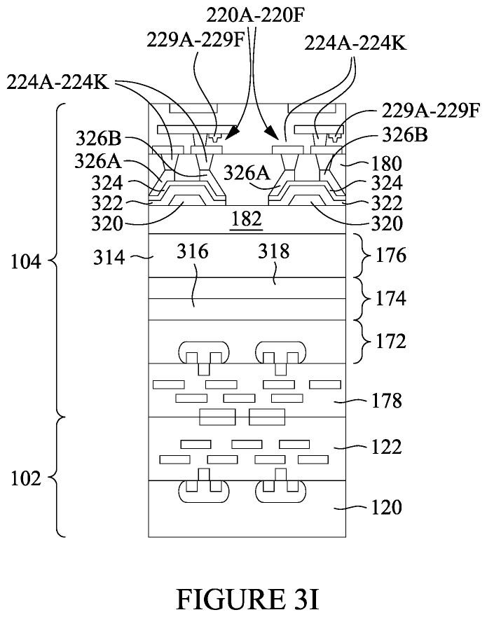

As briefly discussed above, the backside 114 of the first ASIC wafer component 104 includes a backside dielectric layer 180. The backside 114 of the first ASIC wafer component 104 as depicted in FIG. 1 includes one or more transistors 220A, 220B, 220C, 220D, 220E, 220F formed on the oxide layer 182 of the backside layer 176 of the substrate 170. In accordance with one embodiment, the transistors 220A-220F may be implemented as an array thereof, e.g., planar or three-dimensional transistors, as thin-film-transistors, etc. In accordance with one embodiment, the transistors 220A-220F may be implemented as TFT FinFET transistors, or the like. Variations and further discussion of the transistors 220A-220F is provided in greater detail below, with respect to FIGS. 3A-3I, 5A-5I, and 8A-8I.

One or more first metal layer components 222A, 222B, 222C, 222D, 222E, and 222F disposed in the backside dielectric layer 180 are illustrated in FIG. 1. In some embodiments, the one or more first metal layer components 222A-222F are electrically connected to respective transistors 220A-220F by respective first vias 224A, 224B, 224C, 224D, 224E, 224F, 224G, 224H, 224I, 224J, 224K, and 224L. It will be appreciated that such first vias 224A-224L may be fabricated of suitable conductive materials including, for example and without limitation, copper, copper-alloy, aluminum, aluminum-alloy, and the like. In some embodiments, the aforementioned metal layer components 222A-222F may be fabricated of copper, copper alloys, aluminum, aluminum-alloy, or other conductive material.

The first ASIC wafer component 104 further includes one or more top metal layer components 226A, 226B, 226C, 226D, 226E, and 226F, disposed in the backside dielectric layer 180, and electrically connected to respective first metal layer components 222A, 222B, 222C, 222D, 222E, and 222F by second vias 228A, 228B, 228C, 228D, 228E, and 228F. It will be appreciated that such second vias 228A-228F may be fabricated of suitable conductive materials including, for example and without limitation, copper, copper-alloy, aluminum, aluminum-alloy, and the like. In accordance with some embodiments, the one more top metal layer components 226A-226F illustrated in FIG. 1 may be electrically connected to respective metal-insulator-metal (MiM) components 229A, 229B, 229C, 229D, 229E, and 229F, which are respectively coupled to the first metal layer components 222A, 222B, 222C, 222D, 222E, and 222F.

In some embodiments, a redistribution layer (RDL) component 230A, 230B, 230C, 230D, 230E, and 230F are electrically connected to respective top metal components 226A, 226B, 226C, 226D, 226E, and 226F. As shown in FIG. 1, the RDL components 230A-230F extend through the backside anchor layer 186. As illustrated in FIG. 1, the first ASIC wafer component 104 includes one or more anchor pads 232 positioned in or on the backside anchor layer 186.

The CIS device wafer stack 100 of FIG. 1 may further include a third wafer component, i.e., the second ASIC wafer component 106, bonded to the backside anchor layer 186, as shown. In accordance with one embodiment, the second ASIC wafer component 106 depicted in FIG. 1 includes a second ASIC wafer substrate 234 comprising one or more layers. The second ASIC wafer component 106 further includes a second ASIC dielectric layer 236 formed on the substrate 234. The second ASIC wafer component 106 may further include a second ASIC anchor layer 238 formed on the second ASIC dielectric layer 236. The aforementioned anchor layer 238 may be implemented as a suitable dielectric material including, for example and without limitation SiN, oxide, SiOₓF_{y}C_{z}Nₐ, polymer, resin, low-K material, high-K material, or any related insulation layers, or the like.

The second ASIC dielectric layer 236 of the second ASIC wafer component 106 is depicted in FIG. 1 as including one or more first metal layer components 240A, 240B, 240C, and 240D. The second ASIC wafer component 106 further includes one or more second metal layer components 242A, 242B, 242C, and 242D, disposed in the dielectric layer 236, and electrically connected to respective first metal layer components 240A, 240B, 240C, and 240D by first vias 244A, 244B, 244C, and 244D. It will be appreciated that such first vias 244A-244D may be fabricated of suitable conductive materials including, for example and without limitation, copper, copper-alloy, aluminum, aluminum-alloy, and the like.

The second ASIC wafer component 106 further includes one or more third metal layer components 246A, 246B, 246C disposed in the dielectric layer 236 and electrically connected to respective one or more second metal layer components 242A, 242C, 242D by respective second vias 248A, 248B, and 248C. It will be appreciated that such second vias 248A-248C may be fabricated of suitable conductive materials including, for example and without limitation, copper, copper-alloy, aluminum, aluminum-alloy, and the like. As illustrated in FIG. 1, the second ASIC wafer component 106 may further include one or more top metal layer components 250A, 250B, 250C, 250D, 250E, and 250F. The one or more third metal layer components 246A, 246B, 246C are electrically connected, as shown in FIG. 1, to respective top metal layer components 250A, 250C, 250E, and 250F by respective third vias 252A, 252B, 252C, and 252D. It will be appreciated that such third vias 252A-252D may be fabricated of suitable conductive materials including, for example and without limitation, copper, copper-alloy, aluminum, aluminum-alloy, and the like. In some embodiments, the aforementioned metal layer components 240A-240D, 242A-242D, and 246A-246C may be fabricated of copper, copper alloys, aluminum, aluminum-alloy, or other conductive material.

One or more of the aforementioned top metal layer components 250B, 250D, 250F are illustrated in FIG. 1 as being electrically connected via respective fourth vias 256A, 256B, and 256C to suitable metal-insulator-metal (MiM) components 254A, 254B, 254C, which are respectively coupled to the second metal layer components 242B, 242C, and 242D. In some embodiments, a redistribution layer (RDL) component 258A, 258B, 258C 258D, 258E, and 258F is electrically connected to respective top metal components 250A, 250B, 250C, 250D, 250E, and 250F. In some embodiments, the RDL components 258A-258F extend through the second ASIC anchor layer 238, as shown in FIG. 1. As illustrated in FIG. 1, the second ASIC wafer component 106 includes one or more anchor pads 260 positioned in or on the second ASIC anchor layer 238.

In addition, the second ASIC wafer component 106 may include one or more transistor gates or “devices”, i.e., FinFET device, GAA device, HKMG device, SiGe S/D device, SOI device, Poly device, Doped Poly device, etc., comprising a contact 262 coupling a gate component 264 to a first metal layer component 240A-240D, as shown in FIG. 1. These “devices” may be formed on or in the second ASIC substrate 234. As further illustrated in FIG. 1, such “devices” may include the gate component 264, mixed implants 266, a drain 268A, and a source 268B, as will be appreciated.

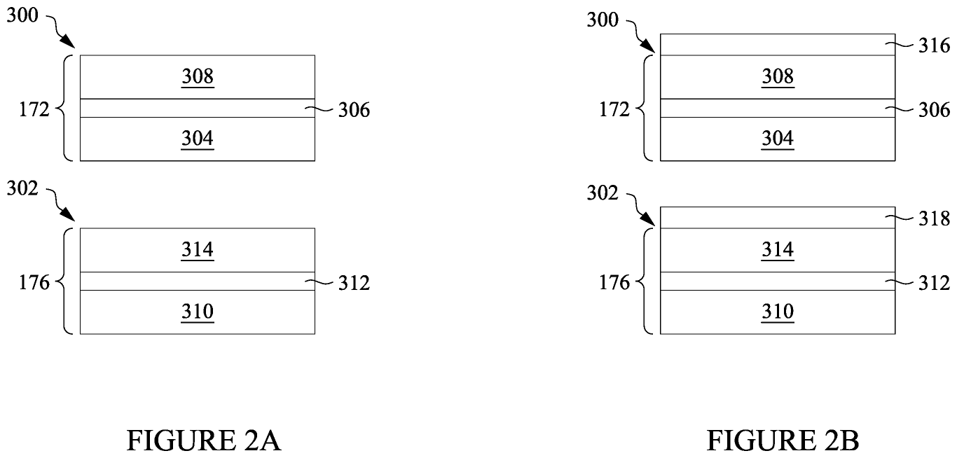

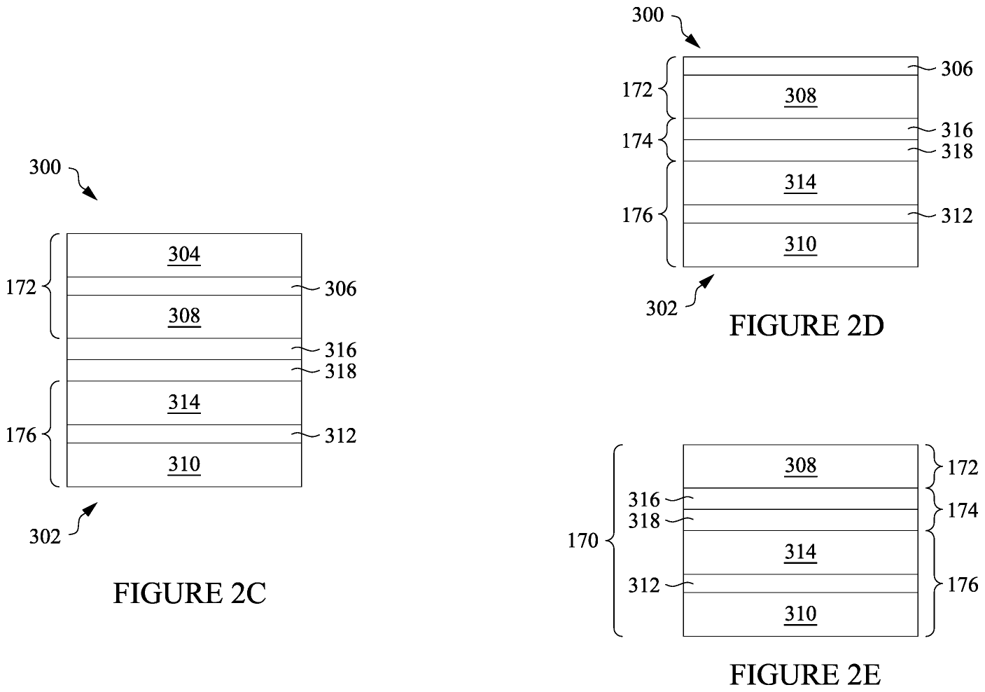

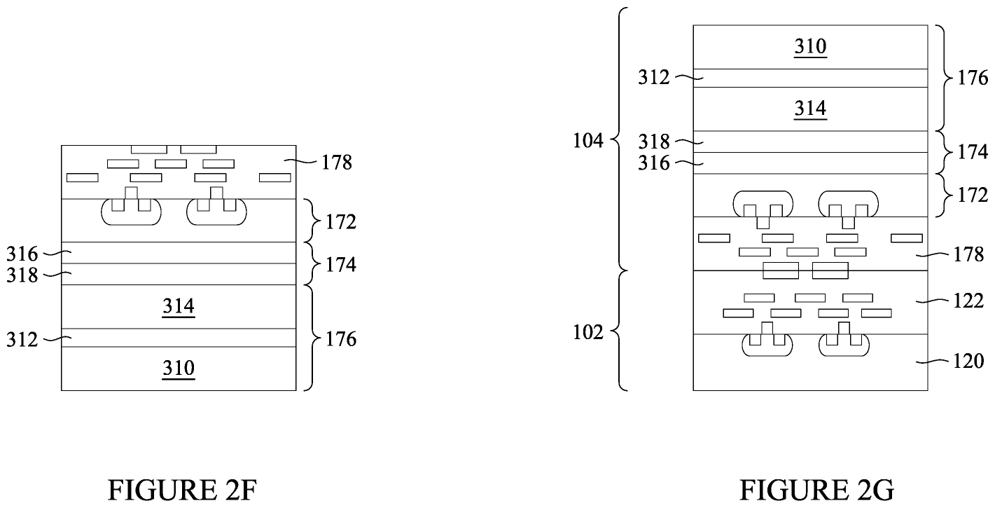

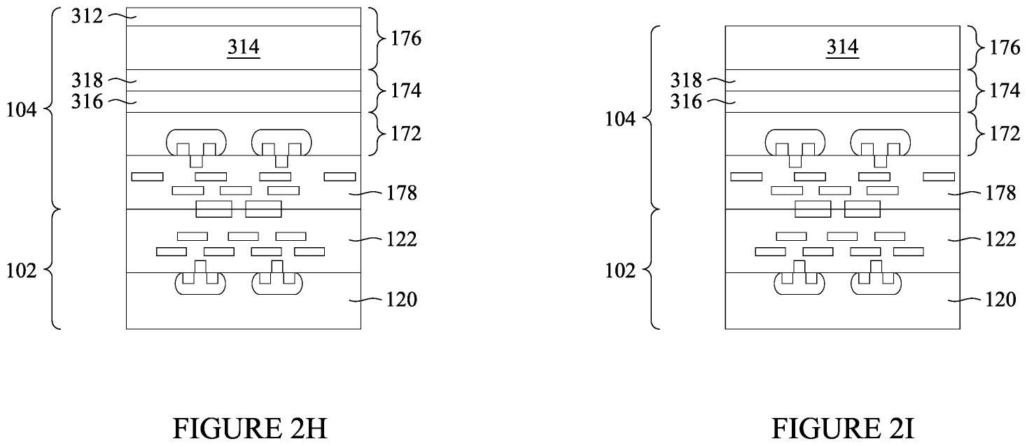

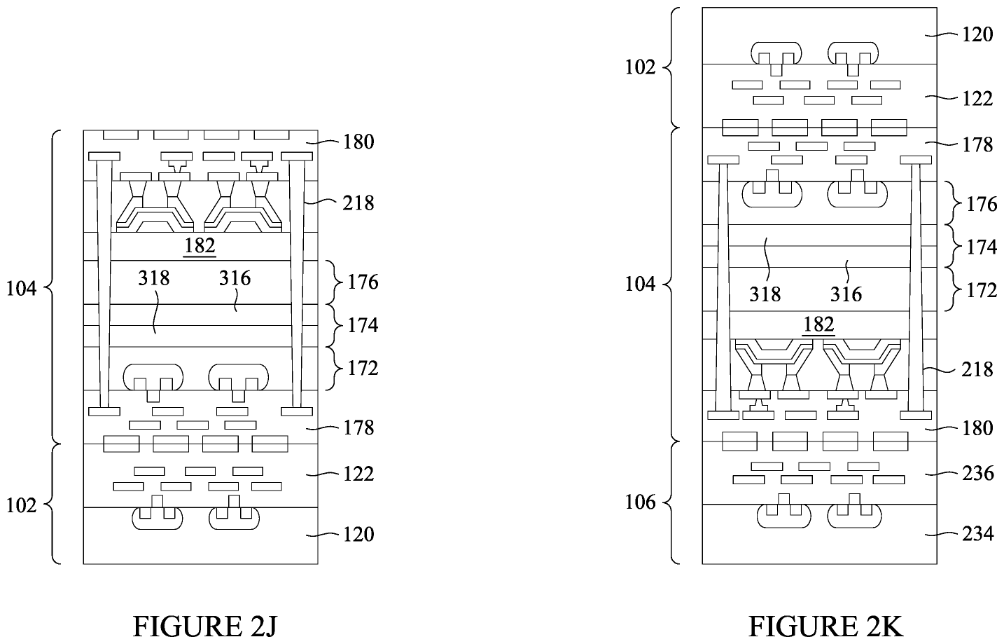

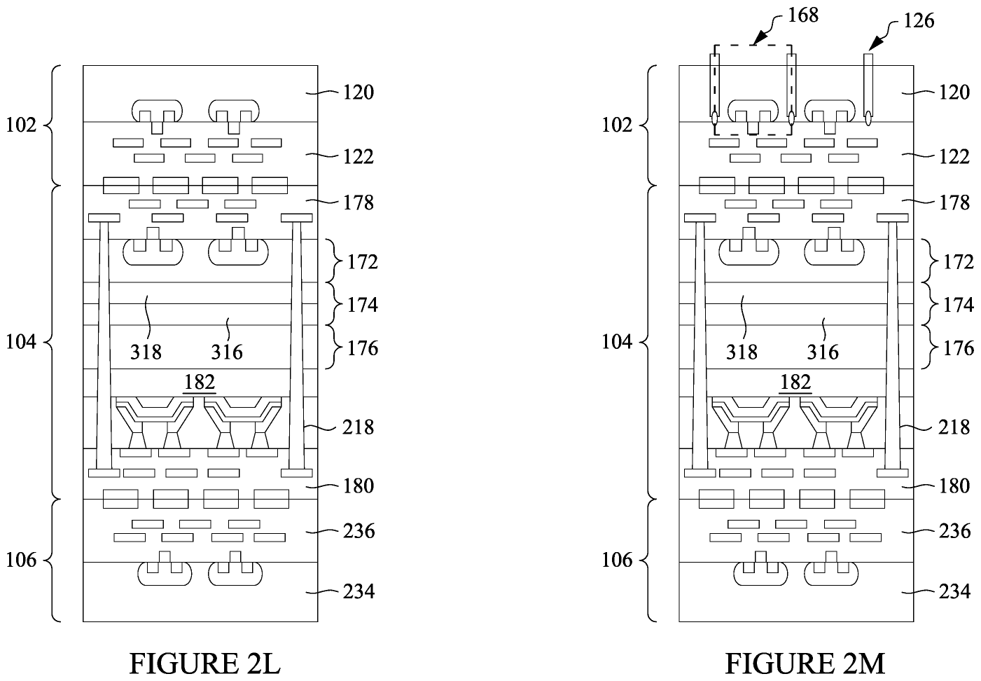

Turning now to FIGS. 2A-2M, there is shown a cross-sectional view of the process flow of fabricating the CIS device wafer stack 100 of FIG. 1. It will be appreciated that FIGS. 2A-2M represent a simplified view of the fabrication process in accordance with one example embodiment and are intended solely to illustrate and not to limit the methods and devices set forth herein. The simplified process begins in FIG. 2A, wherein a device wafer 300 and a carrier wafer 302 are depicted. As shown in FIG. 2A, the device wafer 300 includes a device wafer substrate 304, upon which are formed a device wafer SiGe EPI layer 306 and a Si EPI layer 308. The carrier wafer 302 shown in FIG. 2A includes a carrier wafer substrate 310 upon which are formed a carrier wafer SiGe EPI layer 312 and a carrier wafer Si EPI layer 314. It will be appreciated that the device wafer 300 corresponds, after fabrication, to the frontside layer 172 of the first ASIC wafer substrate 170, and the carrier wafer 302, after fabrication, corresponds to the backside layer 176 of the first ASIC wafer substrate 170.

In FIG. 2B, each of the device wafer 300 and the carrier wafer 302 have a respective SiO2 layer 316 and 318 deposited on their respective Si EPI layers 308 and 314. As shown in FIG. 2C, an oxide-oxide bonding is performed between the device wafer 300 and the carrier wafer 302. That is, the device wafer 300 is inverted and, the SiO2 layer 316 is bonded to the SiO2 layer 318 of the carrier wafer 302. As shown in FIG. 2C, the bonded SiO2 layers 316 and 318 correspond to the SOI layer 172 of the first ASIC wafer substrate 170 depicted in FIG. 1. Thereafter, etching is performed on the device wafer 300, wherein the SiGe EPI layer 306 functions as an etch stop layer, as shown in FIG. 2D.

In FIG. 2E, etching is performed to remove the SiGe EPI layer 306 from the device wafer 300. That is, the Si EPI layer 308 functions as an etch stop layer during removal, i.e., etching, of the SiGe EPI layer 306. It will be appreciated that the resultant device wafer 300 now reflects the frontside layer 172 of the SOI 170 as shown in FIG. 1. Thereafter, in FIG. 2F, portions of the first ASIC wafer component 104 are formed on the frontside layer 172 of the SOI 170. It will be appreciated that intermediate device depicted in FIG. 2F illustrates the first ASIC FEOL/BEOL/RDL formations thereon.

In FIG. 2G, the intermediate device of FIG. 2F is then inverted and hybrid bonded (e.g., a combination of oxide-oxide and metal-metal bonding) to the SOC wafer component 102. The process then continues to FIG. 2H, whereupon carrier wafer substrate 310 is removed, i.e., etched, using the carrier wafer SiGe EPI layer 312 as an etch stop layer. SiGe etching is then performed to remove the SiGe EPI layer 312, as shown in FIG. 2I. FIG. 2J illustrates the subsequent formation of a low temperature IGZO transistor array 220A-220F on an oxide layer 182, the formation of various metal layer components, RDL components, MiM components, etc., and finalization of the first ASIC wafer component 104, i.e., both the frontside 112 and the backside 114 of the first ASIC wafer component 104 are now illustrated in FIG. 2J. Discussion and description of the aforementioned IGZO transistors is provided below, with respect to FIGS. 3A-3I. The second ASIC wafer component 106 is then bonded to the backside 114 of the first ASIC wafer component 104, and the combined wafer stack is inverted, placing the backside 110 of the SOC wafer component 102 at the top of the page, as shown in FIG. 2K. That is, the wafer stack is flipped to enable further processing on the SOC wafer component 102, as discussed in FIG. 2L.

In FIG. 2L, the backside 110 of the SOC wafer component 102, i.e., the SOC substrate 120 is thinned as shown. In some embodiments, CMP or other mechanical or chemical methodologies are used to thin the SOC substrate 120, as will be appreciated. Thereafter, in FIG. 2M, metal gate formation is performed, i.e., the composite metal grid 126 and associated components are formed. Although not shown, it will be appreciated that after FIG. 2M, individual dies or chips may then be separated from the wafer stack.

Turning now to FIGS. 3A-3I, there is shown a simplified cross-sectional flow process of forming the planar transistors 220A-220F of FIGS. 1-2M in accordance with one example embodiment. The process begins in FIG. 3A, whereupon an oxide layer 182 is deposited on the backside layer 176 of the SOI substrate 170, i.e., on the carrier wafer Si EPI layer 314 as described in FIGS. 2A-2M. In some embodiments, the oxide layer 182 may comprise, for example and without limitation, an aluminum-oxide layer (e.g., Al₂O₃), or the like. In FIG. 3B, a gate 320 is formed on the oxide layer 182. That is, FIG. 3B illustrates the result of depositing gate material, e.g., TiN, or the like, photoresist, patterning, etching, photoresist removal, etc.

An HK film 322 is then formed on each gate 320 as illustrated in FIG. 3C. In some embodiments, formation of the HK film 322 may include, for example and without limitation, deposition of the HK material, e.g., HfO2 or the like, on the gates 320, followed by photoresist application, patterning, etching, photoresist removal, etc. An IGZO channel 324 is then formed on the HK film 322 and gate 320, as shown in FIG. 3D. According to some embodiments, formation of the IGZO channel 324 may include, for example and without limitation, deposition of IGZO material, on the HK film 322, followed by photoresist application, patterning, etching, photoresist removal, etc.

In FIG. 3E, a source 326A and a drain 326B are formed on IGZO channel 324, thereby completing fabrication of the planar transistor(s) 220A-220F depicted in FIGS. 1-2M. In accordance with some embodiments, formation of the source 326A and drain 326B may include, for example and without limitation, deposition of the source/drain material, e.g., TiN, or the like, photoresist, patterning, etching, photoresist removal, etc. In FIG. 3F, a dielectric layer 180, i.e., an oxide layer or other insulative layer, is deposited on the backside 114 of the first ASIC wafer component 104.

Etching for contacts, i.e., the first vias 224A-224L of FIG. 1, is then performed. FIG. 3G provides an illustration of the contact paths 328 formed through the backside dielectric layer 180. Formation of such contact paths 328 may include, for example and without limitation, photoresist application, patterning, etching, and photoresist removal, as will be appreciated. Thereafter, as shown in FIG. 3H, metal routing is applied to finalize formation of the backside 114 of the first ASIC wafer component 104. In accordance with one embodiment, one or more MiM components 229A-229F may be positioned between metal routing, i.e., metal layer components, as shown in FIG. 3I.

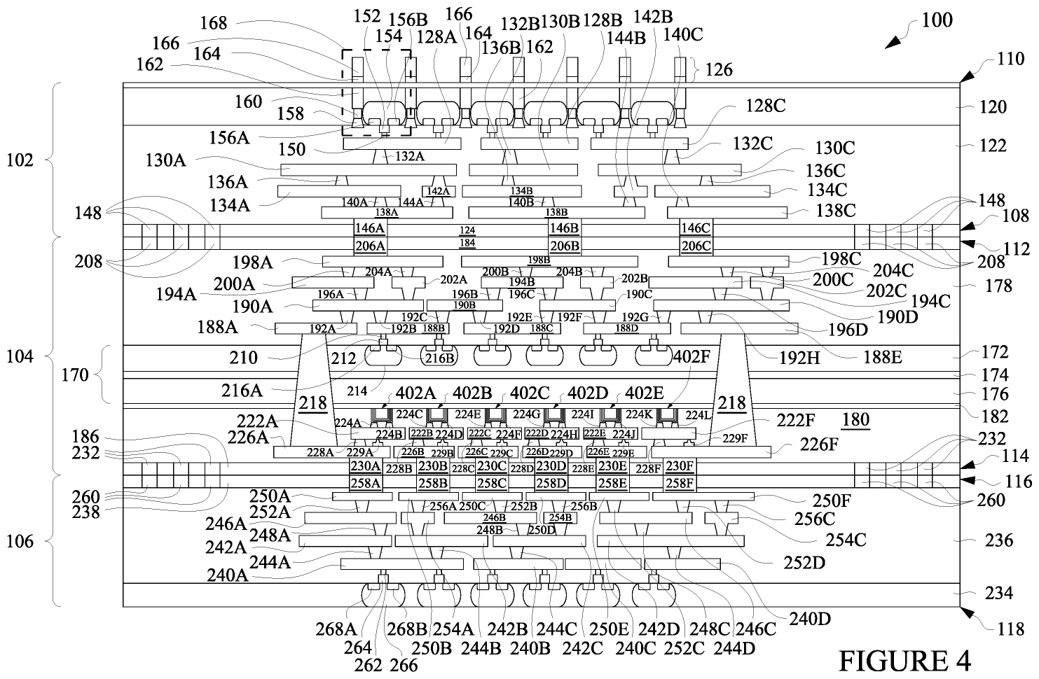

Turning now to FIG. 4, there is shown a CIS device wafer stack 400 in accordance with a second embodiment. That is, FIG. 4 provides a diagrammatic cross-sectional view of a CIS wafer stack 400 similar to the wafer stack 100 of FIG. 1. Accordingly, as shown in FIG. 4, the wafer stack 400 includes the first SOC wafer component 102, the first ASIC wafer component 104, and the second ASIC wafer component 106. As illustrated in FIG. 4, the first SOC wafer component 102 and the second ASIC wafer component 106 are identical to those in FIG. 1. Accordingly, the various components described above with respect to the first SOC wafer component 102 and the second ASIC wafer component 106 apply to FIG. 4.

The first ASIC wafer component 104 shown in FIG. 4 utilizes an array of three-dimensional transistors 402A, 402B, 402C, 402D, 402E, and 402F in place of the planar transistors 220A-220F. That is, the backside 114 of the first ASIC wafer component 104 as depicted in FIG. 4 includes the one or more transistors 402A, 402B, 402C, 402D, 402E, and 402F formed on the oxide layer 182 of the backside layer 176 of the substrate 170. In accordance with one embodiment, the transistors 402A-402F may be implemented as an array thereof. In the exemplary embodiment of FIG. 4, the transistors 402A-402F are three-dimensional transistors, such as, for example and without limitation, as thin-film-transistors, etc. In accordance with one embodiment, the transistors 402A-402F may be implemented as three-dimensional TFT FinFET transistors, or the like. In such an embodiment, the three-dimensional TFT FinFET transistors may be 3D TFT IGZO transistors utilizing a gate (TIN), Source/Drain (TIN), High-K dielectric film (HfOx), and IGZO channel (InGaZnO).

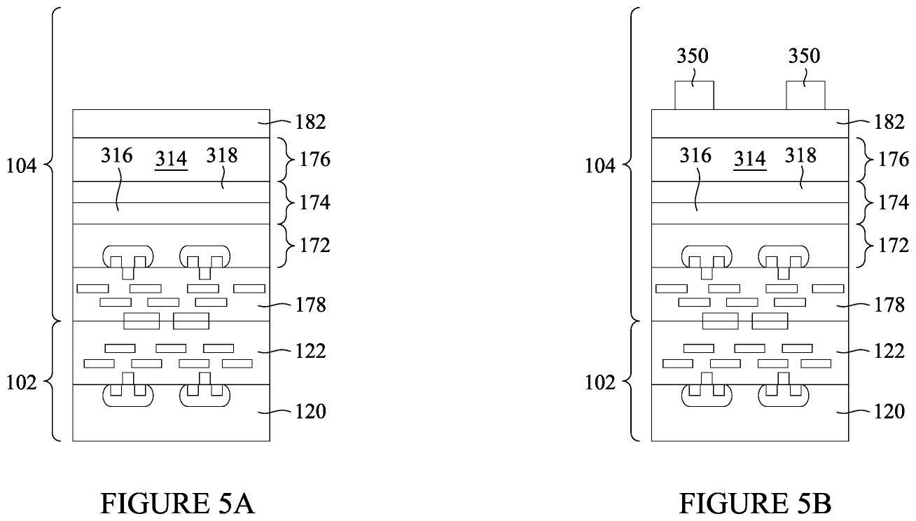

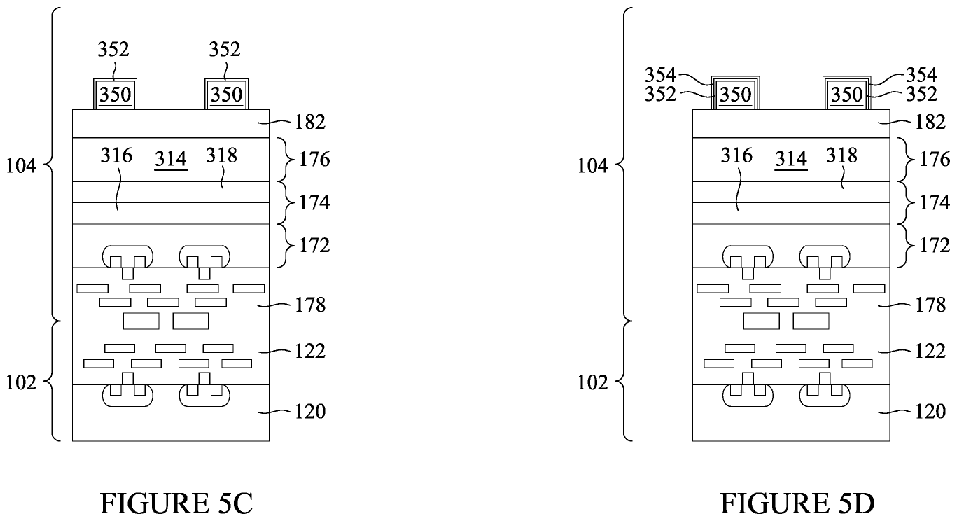

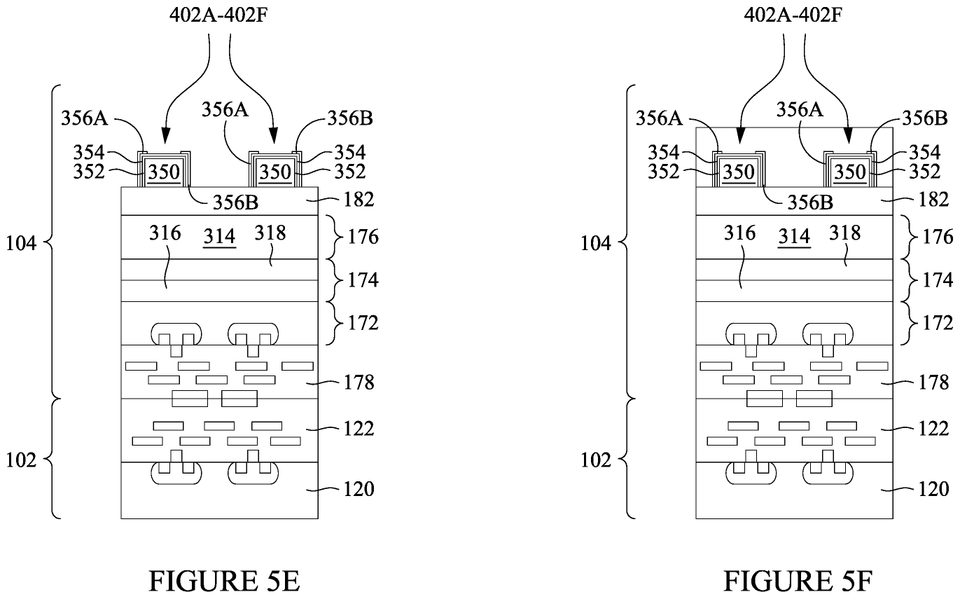

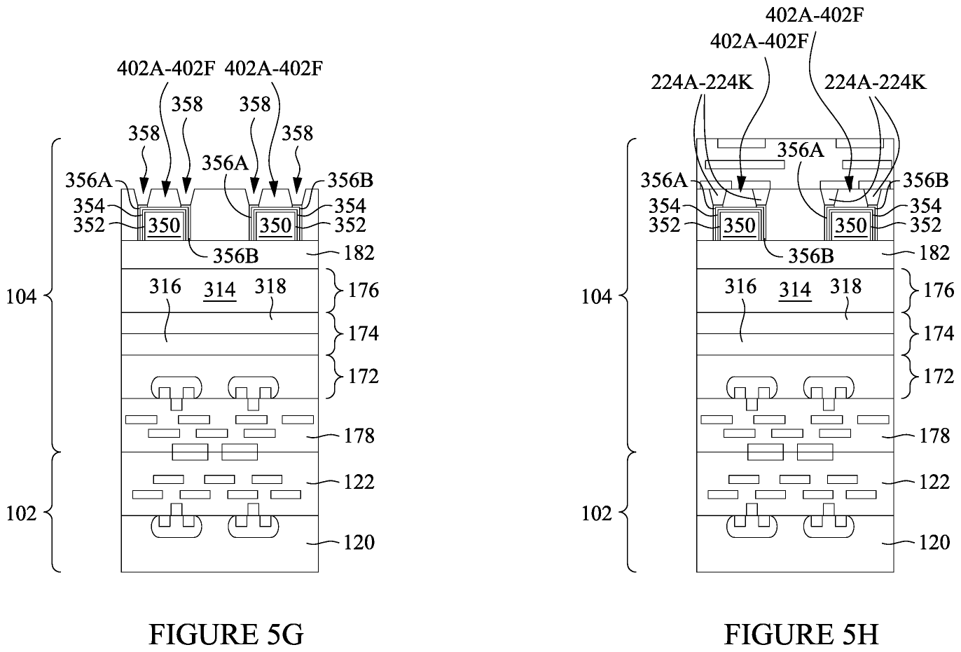

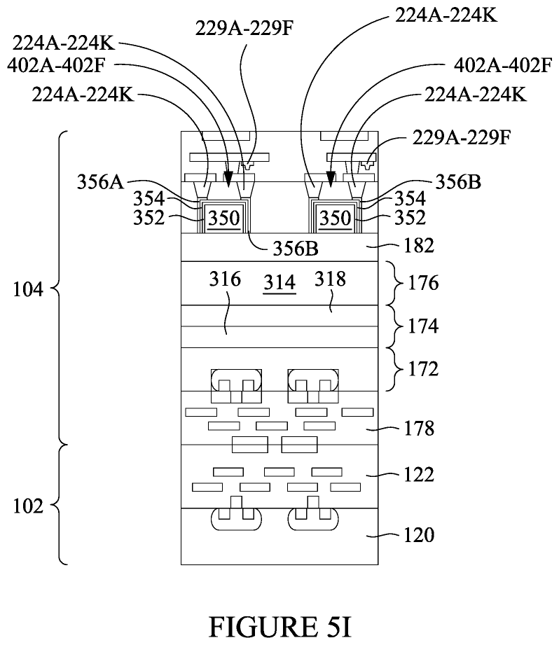

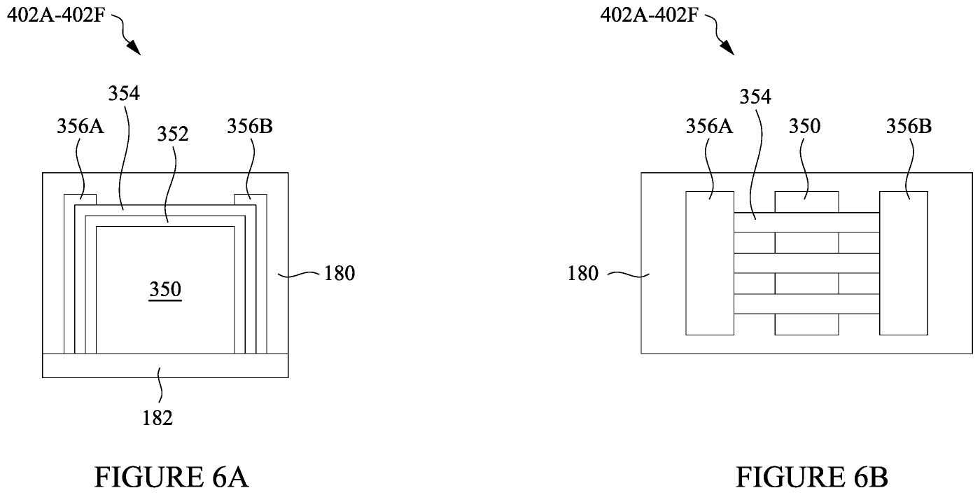

Formation of the three-dimensional transistors 402A-402F is illustrated in greater detail below with respect to FIGS. 5A-6B. Turning now to FIGS. 5A-5I, there is shown a simplified cross-sectional flow process of forming the three-dimensional transistors 402A-402F used in the CIS device wafer stack 400 of FIG. 4 according to one example embodiment. The process begins in FIG. 5A, whereupon an oxide layer 182 is deposited on the backside layer 176 of the SOI substrate 170, i.e., on the carrier wafer Si EPI layer 314 as described in FIGS. 2A-2M. In some embodiments, the oxide layer 182 may comprise, for example and without limitation, an aluminum-oxide layer (e.g., Al₂O₃), or the like. In FIG. 5B, a gate 350 is formed on the oxide layer 182. That is, FIG. 5B illustrates the result of depositing gate material, e.g., TiN, or the like, photoresist, patterning, etching, photoresist removal, etc.

An HK film 352 is then formed on each gate 350 as illustrated in FIG. 5C. In some embodiments, formation of the HK film 352 may include, for example and without limitation, deposition of the HK material, e.g., HfO2 or the like, on the gates 350, followed by photoresist application, patterning, etching, photoresist removal, etc. An IGZO channel 354 is then formed on the HK film 352 and gate 350, as shown in FIG. 5D. According to some embodiments, formation of the IGZO channel 354 may include, for example and without limitation, deposition of IGZO material, on the HK film 352, followed by photoresist application, patterning, etching, photoresist removal, etc.

In FIG. 5E, a source 356A and a drain 356B are formed on IGZO channel 354, thereby completing fabrication of the three-dimensional transistor(s) 402A-402F depicted in FIG. 4. In accordance with some embodiments, formation of the source 356A and drain 356B may include, for example and without limitation, deposition of the source/drain material, e.g., TiN, or the like, photoresist, patterning, etching, photoresist removal, etc. In FIG. 4F, a dielectric layer 180, i.e., an oxide layer or other insulative layer, is deposited on the backside 114 of the first ASIC wafer component 104.

Etching for contacts, i.e., the first vias 224A-224L of FIG. 4, is then performed. FIG. 5G provides an illustration of the contact paths 358 formed through the backside dielectric layer 180. Formation of such contact paths 358 may include, for example and without limitation, photoresist application, patterning, etching, and photoresist removal, as will be appreciated. Thereafter, as shown in FIG. 5H, metal routing is applied to finalize formation of the backside 114 of the first ASIC wafer component 104. FIG. 5I illustrates a further embodiment, wherein one or more MiM components 229A-229F may be positioned between metal routing, i.e., metal layer components.

Referring now to FIGS. 6A and 6B, there are respectively shown a diagrammatic cross-sectional view (FIG. 6A) and top view (FIG. 6B) of the three-dimensional transistors 402A-402F used in the CIS device wafer stack 400 of FIGS. 4-5I. In FIGS. 6A and 6B, the gate 350, the HK film 352, the IGZO channel 354, the source 356A, and the drain 356B of each three-dimensional transistor 402A-402F are shown.

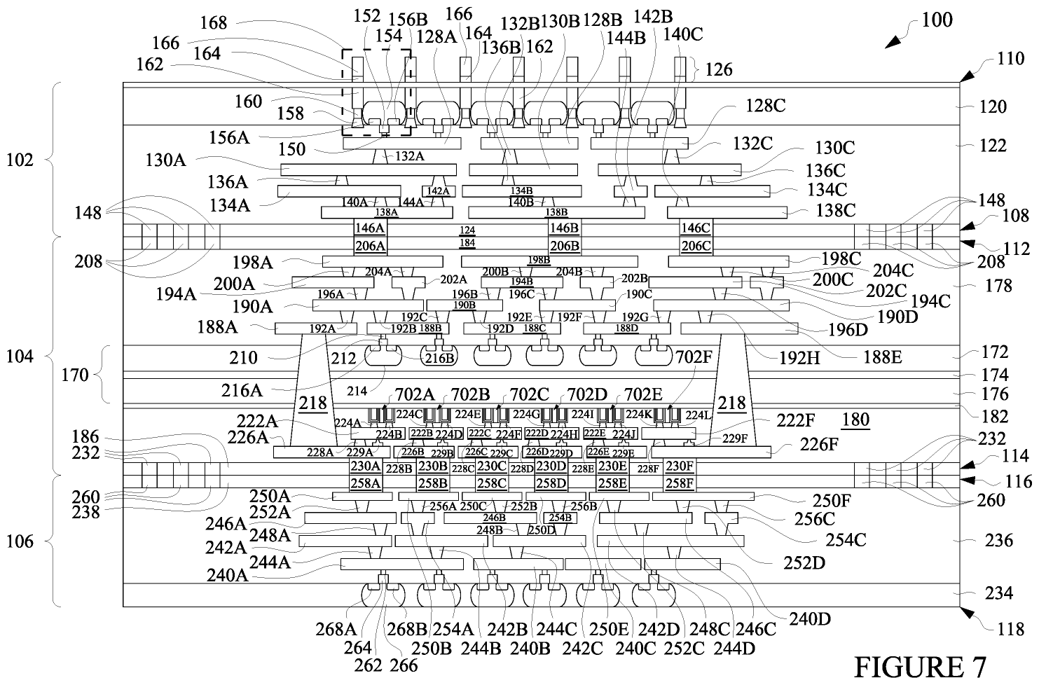

Turning now to FIG. 7, there is shown a CIS device wafer stack 700 in accordance with a third embodiment. That is, FIG. 7 provides a diagrammatic cross-sectional view of a CIS wafer stack 700 similar to the wafer stack 100 of FIG. 1 and the CIS wafer stack 400 of FIG. 4. Accordingly, as shown in FIG. 7, the wafer stack 700 includes the first SOC wafer component 102, the first ASIC wafer component 104, and the second ASIC wafer component 106. As illustrated in FIG. 7, the first SOC wafer component 102 and the second ASIC wafer component 106 are identical to those in FIG. 1 and FIG. 4. Accordingly, the various components described above with respect to the first SOC wafer component 102 and the second ASIC wafer component 106 apply to FIG. 7.

The first ASIC wafer component 104 shown in FIG. 7 utilizes an array of three-dimensional transistors 702A, 702B, 702C, 702D, 702E, and 702F in place of the planar transistors 220A-220F of FIG. 1 and the three-dimensional transistors 402A-402F of FIG. 4. Accordingly, as depicted in FIG. 7, the backside 114 of the first ASIC wafer component 104 includes the one or more transistors 702A, 702B, 702C, 702D, 702E, and 702F formed on the oxide layer 182 of the backside layer 176 of the substrate 170. In accordance with one embodiment, the three-dimensional transistors 702A-702F may be implemented as an array thereof. In the exemplary embodiment of FIG. 7, the transistors 702A-702F are three-dimensional transistors, such as, for example and without limitation, as thin-film-transistors, etc. In accordance with one embodiment, the transistors 702A-702F may be implemented as three-dimensional TFT FinFET transistors, or the like. In such an embodiment, the three-dimensional TFT FinFET transistors may be 3D TFT IGZO transistors utilizing a gate (TIN), Source/Drain (TIN), High-K dielectric film (HfOx), and IGZO channel (InGaZnO).

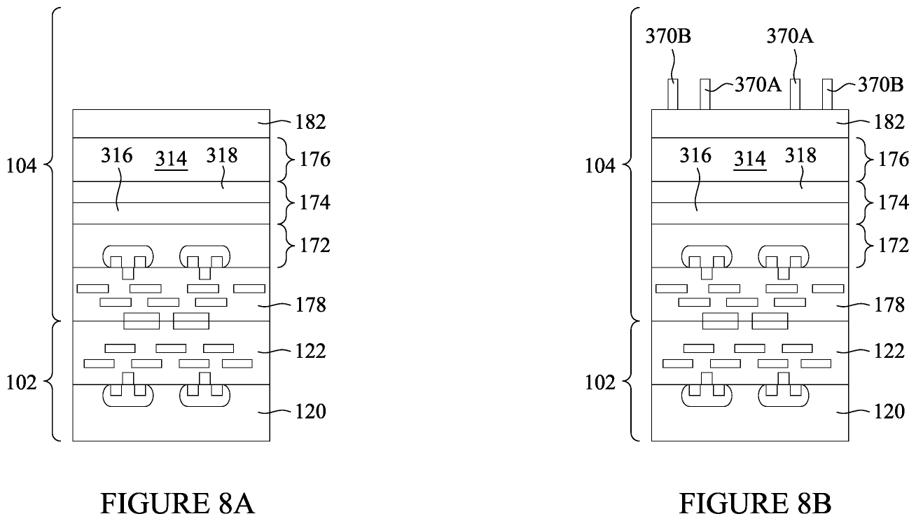

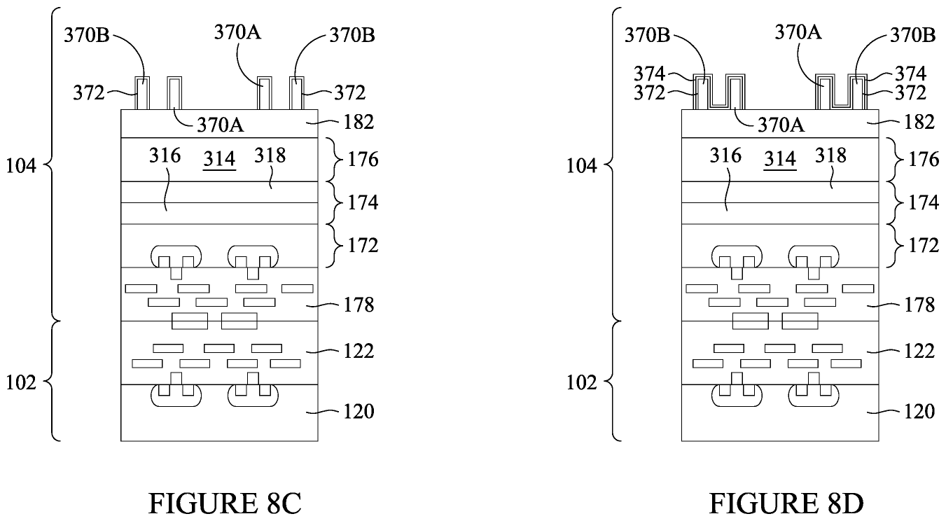

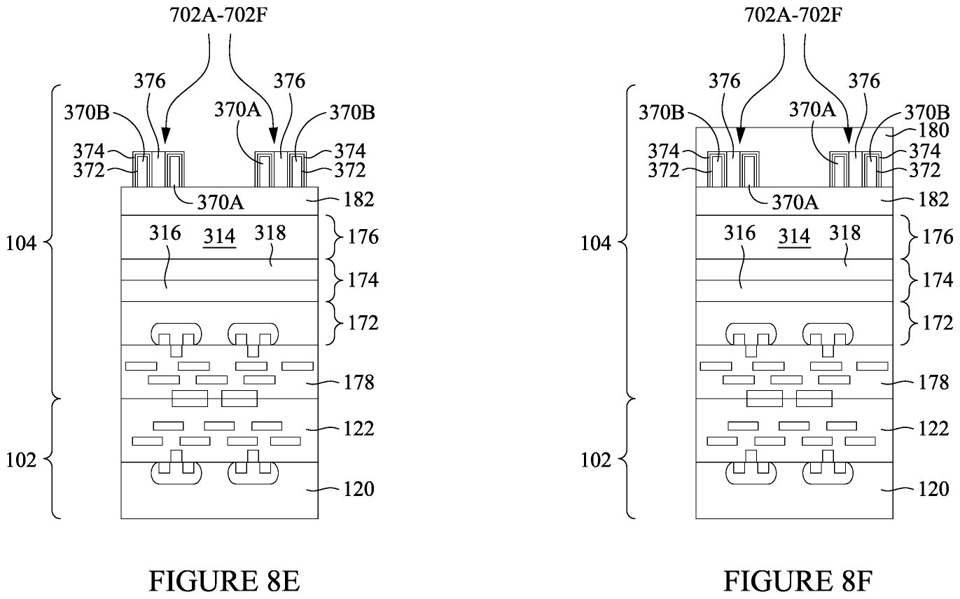

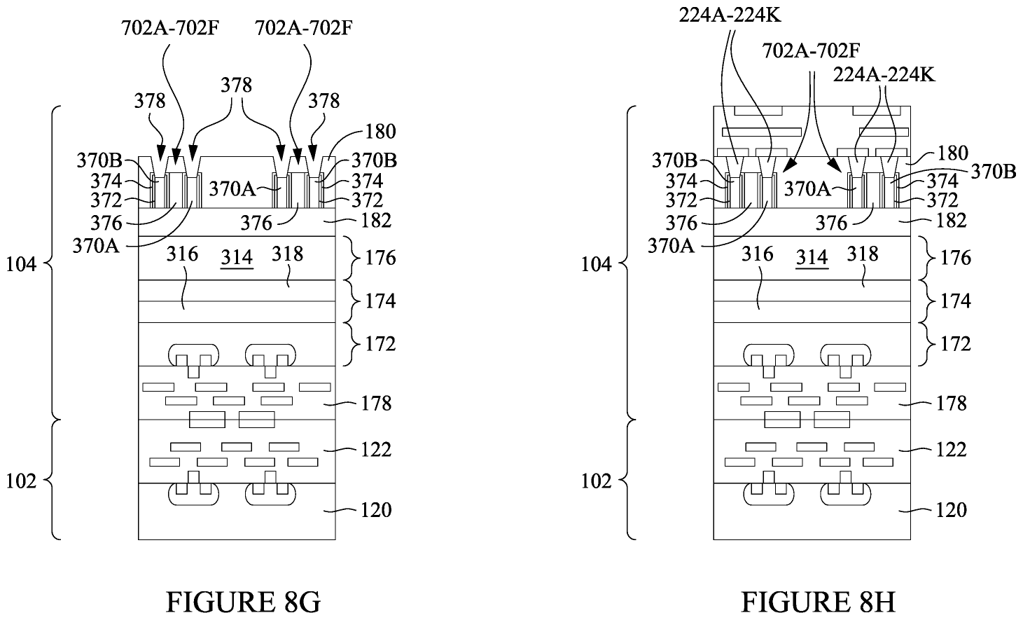

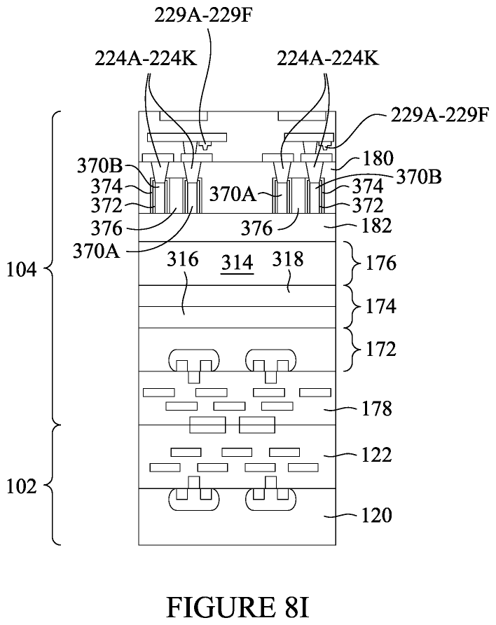

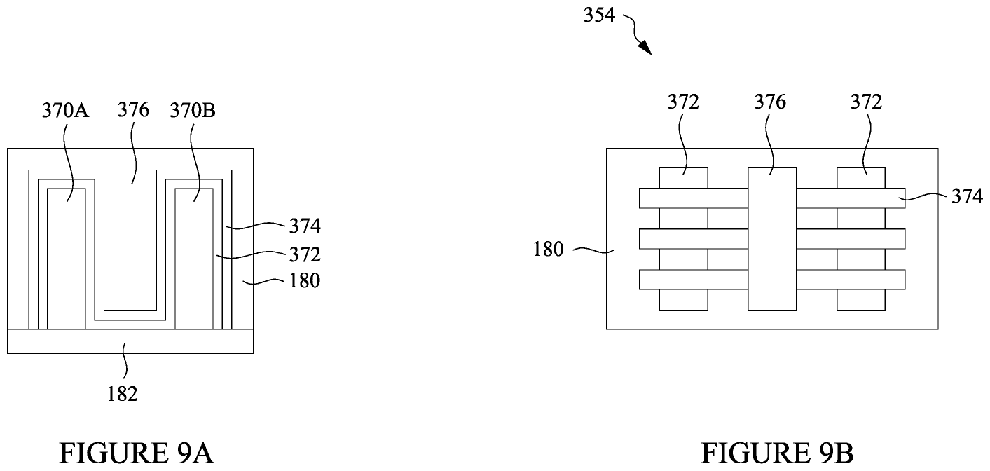

Formation of the three-dimensional transistors 702A-702F is illustrated in greater detail below with respect to FIGS. 8A-9B. Turning now to FIGS. 8A-8I, there is shown a simplified cross-sectional flow process of forming the three-dimensional transistors 702A-702F used in the CIS device wafer stack 700 of FIG. 7 according to one example embodiment. The process begins in FIG. 8A, whereupon an oxide layer 182 is deposited on the backside layer 176 of the SOI substrate 170, i.e., on the carrier wafer Si EPI layer 314 as described in FIGS. 2A-2M. In some embodiments, the oxide layer 182 may comprise, for example and without limitation, an aluminum-oxide layer (e.g., Al₂O₃), or the like. In FIG. 8B, a source 370A and a drain 370B is formed on the oxide layer 182. That is, FIG. 8B illustrates the result of depositing source/drain material, e.g., TiN, or the like, photoresist, patterning, etching, photoresist removal, etc.

An IGZO channel 372 is then formed on the source 370A and drain 370, as shown in FIG. 5C. According to some embodiments, formation of the IGZO channel 372 may include, for example and without limitation, deposition of IGZO material, on the source/drain 370A-370B, followed by photoresist application, patterning, etching, photoresist removal, etc. An HK film 374 is then formed on each source/drain 370A-370B as illustrated in FIG. 8D. In some embodiments, formation of the HK film 352 may include, for example and without limitation, deposition of the HK material, e.g., HfO2 or the like, on the source/drain 370A-370B, followed by photoresist application, patterning, etching, photoresist removal, etc.

In FIG. 8E, a gate 376 is formed on HK film 374, thereby completing fabrication of the three-dimensional transistor(s) 702A-702F depicted in FIG. 5. In accordance with some embodiments, formation of the gate 376 may include, for example and without limitation, deposition of the source/drain material, e.g., TiN, or the like, photoresist, patterning, etching, photoresist removal, etc. In FIG. 8F, a dielectric layer 180, i.e., an oxide layer or other insulative layer, is deposited on the backside 114 of the first ASIC wafer component 104.

Etching for contacts, i.e., the first vias 224A-224L of FIG. 7, is then performed. FIG. 8G provides an illustration of the contact paths 378 formed through the backside dielectric layer 180. Formation of such contact paths 378 may include, for example and without limitation, photoresist application, patterning, etching, and photoresist removal, as will be appreciated. Thereafter, as shown in FIG. 8H, metal routing is applied to finalize formation of the backside 114 of the first ASIC wafer component 104. In accordance with one embodiment, one or more MiM components 229A-229F may be positioned between metal routing, i.e., metal layer components, as shown in FIG. 8I.

Referring now to FIGS. 9A and 9B, there are respectively shown a diagrammatic cross-sectional view (FIG. 9A) and top view (FIG. 9B) of the three-dimensional transistors 702A-702F used in the CIS device wafer stack 700 of FIGS. 7-8I. In FIGS. 9A and 9B, the gate 376, the HK film 374, the IGZO channel 372, the source 370A, and the drain 370B of each three-dimensional transistor 702A-702F are shown.

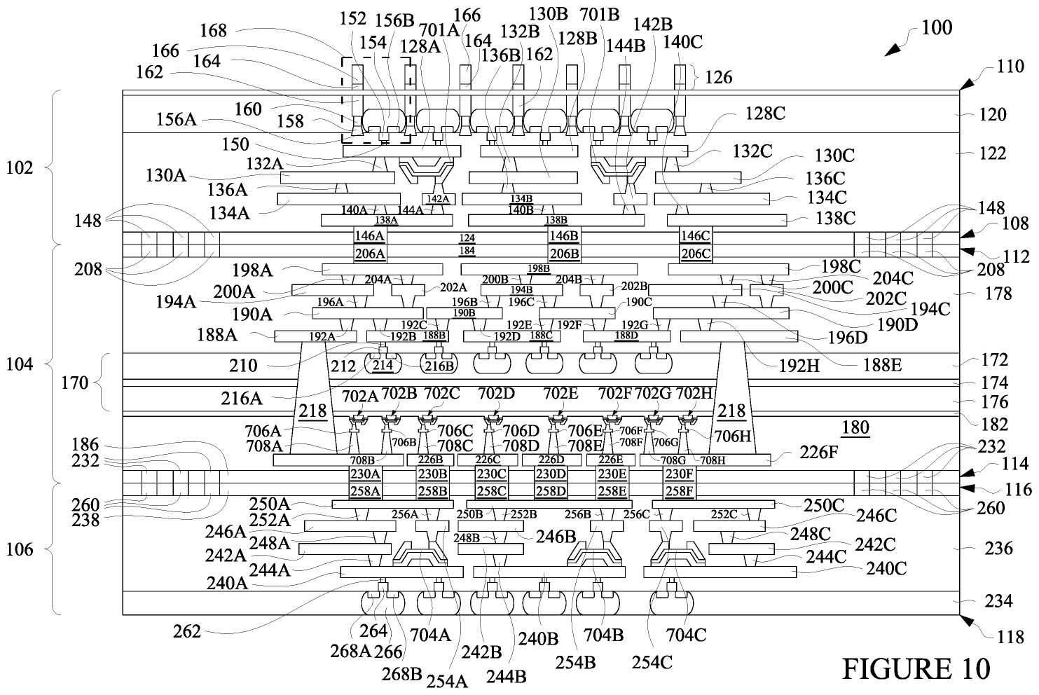

Turning now to FIG. 10, there is provided a cross-sectional view of a CIS device wafer stack 1000 in accordance with a fourth embodiment of the subject disclosure. As shown in FIG. 10, the CIS device wafer stack 1000 comprises a first SOC wafer component 102, a first ASIC wafer component 104, and a second ASIC wafer component 106. It will be appreciated that the CIS device wafer stack 1000 is a representative, non-limiting example of one possible implementation of the systems and methods described herein. As illustrated in FIG. 10, similar to the embodiments described above with respect to FIGS. 1, 4, and 7, the first SOC wafer component 102 includes a first SOC wafer frontside 108 and a first SOC wafer backside 110. The first ASIC wafer component 104 includes a first ASIC wafer frontside 112 and first ASIC wafer backside 114. Similarly, the second ASIC wafer component 106 includes a second ASIC wafer frontside 116 and a second ASIC wafer backside 118. In the embodiment of FIG. 10, the first SOC wafer frontside 108 is bonded to the first ASIC wafer frontside 112, and the first ASIC wafer backside 114 is bonded to the second ASIC wafer frontside 116. Variations on the wafer stacking i.e., frontside/backside bonding, as illustrated in FIG. 10 are contemplated herein and the illustration of the ordering in FIG. 10 is intended solely as one example of such order of wafer stacking in accordance with some embodiments. Furthermore, it will be appreciated that the wafer stack 1000 may include a single ASIC wafer component and two SOC wafer components, three SOC wafer components, three ASIC wafer components, or four or more wafer components utilizing the connectivity, layout, features, and bonds, as described herein.

As discussed above, the first ASIC wafer component 104, may include, for example and without limitation, logic circuitry, ADC (analog-to-digital converter), ISP (image signal processor), and the like. The second ASIC wafer component 106, may include, for example and without limitation, logic circuits, ISP (image signal processor), ADC (analog-to-digital converter), and the like.

In the example embodiment depicted in FIG. 10, the first SOC wafer component 102 includes an SOC substrate 120, a dielectric layer 122, and an anchor layer 124. In some embodiments, the SOC substrate 120 may be implemented as a semiconducting material. Such materials can include silicon, for example and without limitation, in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the SOC substrate 120 is silicon.

As illustrated in FIG. 10, the dielectric layer 122 may comprise an insulating material, such as silicon dioxide (SiO₂) or silicon nitride (SiN), silicon oxynitride (SiON), fluoride-doped silicate glass, or other dielectric material. The aforementioned anchor layer 124 may be implemented as a suitable dielectric material including, for example and without limitation SiN, oxide, SiOₓF_{y}C_{z}Nₐ, polymer, resin, low-K material, high-K material, or any related insulation layers, as will be appreciated. In some embodiments, the dielectric layer 122 and the anchor layer 124 may be implemented as the same or different materials.

The dielectric layer 122 of the SOC wafer component 102 is depicted in FIG. 1 as including one or more first metal layer components 128A, 128B, and 128C. Disposed in the dielectric layer 122 are one or more second metal layer components 130A, 130B, 130C, electrically connected to respective first metal layer components 128A, 128B, 128C by respective first vias 132A, 132B, 132C. It will be appreciated that such first vias 132A-132C may be fabricated of suitable conductive materials including, for example and without limitation, copper, copper-alloy, aluminum, aluminum-alloy, and the like. The SOC wafer component 102 further includes one or more third metal layer components 134A, 134B, 134C disposed in the dielectric layer 122 and electrically connected to respective one or more second metal layer components 130A, 130B, 130C by respective second vias 136A, 136B, 136C. It will be appreciated that such second vias 136A-136C may be fabricated of suitable conductive materials including, for example and without limitation, copper, copper-alloy, aluminum, aluminum-alloy, and the like. The one or more third metal layer components 134A, 134B, 134C are connected to respective one or more top metal layer components 138A, 138B, 138C by respective third vias 140A, 140B, 140C. In accordance with some embodiments, the third vias 140A-140C may be fabricated of suitable conductive materials including, for example and without limitation, copper, copper-alloy, aluminum, aluminum-alloy, metal, metal alloy, or the like.

The SOC wafer component 102 of FIG. 10 further illustrates one or more planar transistors 701A, 701B formed on respective first metal layer components 128A and 128C. The planar transistors 701A-701B are described in greater detail above with respect to FIGS. 3A-3I. At least one of the source or drain of the planar transistors 701A-701B are electrically connected to suitable metal-insulator-metal (MiM) components 142A and 142B, which are respectively coupled to the top metal layer components 138A and 138B via respective fourth vias 144A and 144B. It will be appreciated that the combination of a planar transistor 701A-701B and MiM component 142A-142B correspond to a 1T1C component, i.e., a one-transistor, one-capacitor component.

In some embodiments, a redistribution layer (RDL) component 146A, 146B, 146C is electrically connected to respective top metal components 138A, 138B, 138C, the RDL components 146A-146C extending through the SOC anchor layer 124, as shown in FIG. 10. In some embodiments, the metal layer components 128A-128C, 130A-130C, 134A-134C, and 138A-138C may be fabricated of copper, copper alloys, aluminum, aluminum-alloy, or other conductive material.

As illustrated in FIG. 10, the SOC wafer component 102 includes one or more anchor pads 148 positioned in or on the anchor layer 124 on the frontside 108. The anchor pads 148 may be implemented as, for example and without limitation, copper, copper-alloy, aluminum, aluminum-alloy, metal, metal alloy, etc., configured to provide one or more connection or attachment points between the SOC wafer component 102 and/or the first ASIC wafer component 104.

The backside 110 of the first SOC wafer component 102, i.e., the side of the SOC substrate 120 depicted as the top of the CIS device wafer stack 1000 includes a composite metal grid 126 extending perpendicularly from the SOC substrate 120. The backside 110 of the SOC wafer component 102 may include a variety of components, as will be appreciated. As with the embodiment presented in FIG. 1, the SOC wafer component 102 of FIG. 10 includes one or more photodiodes 168, as described in greater detail above with respect to FIG. 1.

The first ASIC wafer component 104 depicted in FIG. 10 includes a first ASIC wafer substrate 170 comprising one or more layers. In the example embodiment of FIG. 10, the substrate 170 comprises a frontside layer 172, a silicon-on-insulator (SOI) layer 174, and a backside layer 176. According to some embodiments, the frontside layer 172 and the backside layer 176 may comprise, for example and without limitation, non-low-k dielectric materials such as silicon oxide, silicon carbide (SiC), silicon carbo-nitride (SiCN), silicon oxy-carbo-nitride (SiOCN), or the like. In the illustration of FIG. 10, the SOI layer 174 may comprise, for example and without limitation silicon oxide, or other suitable insulative material. As shown in FIG. 10, the first ASIC wafer component 104 may be implemented with components, i.e., functionality, formed on both the frontside 112 and the backside 114 of the component 104. That is, fabrication of components may be built upon the frontside layer 172 and the backside layer 176 of the substrate 170, with components formed thereon electrically connected between the frontside 112 and backside 114 using Big Through Silicon Vias (BTSV) 218, i.e., large through-silicon-vias that extend through the entire substrate 170 (e.g., frontside layer 172, SOI layer 174 and backside layer 176), enabling connectivity of components disposed in the frontside layer 172 with components disposed in the backside layer 176, as illustrated in FIG. 10. It will be appreciated that such BTSVs 218 may be fabricated of suitable conductive materials including, for example and without limitation, copper, copper-alloy, aluminum, aluminum-alloy, and the like.

The frontside 112 of the first ASIC wafer component 104 of FIG. 10 is described in greater detail above with respect to FIG. 1. As with the first ASIC wafer component 104 of FIG. 1, an oxide layer 182 may be formed on the backside layer 176 of the substrate 170, as illustrated in FIG. 10. In some embodiments, the oxide layer 182 may comprise, for example and without limitation, an aluminum-oxide layer (e.g., Al₂O₃), or the like. The first ASIC wafer component 104 may further include a frontside anchor layer 184 formed on the frontside dielectric layer 178 and a backside anchor layer 186 formed on the backside dielectric layer 180. The aforementioned anchor layers 184-186 may be implemented as a suitable dielectric material including, for example and without limitation SiN, oxide, SiOₓF_{y}C_{z}Nₐ, polymer, resin, low-K material, high-K material, or any related insulation layers, as will be appreciated. The other components illustrated in FIG. 10 on the frontside 112 of the first ASIC wafer component 104 are described above with respect to FIG. 1.

The embodiment presented in FIG. 10 illustrates the backside 114 of the first ASIC wafer component 104 having a backside dielectric layer 180. The backside 114 of the first ASIC wafer component 104 as depicted in FIG. 10 includes one or more transistors 702A, 702B, 702C, 702D, 702E, 702F, 702G, and 702H formed on the oxide layer 182 of the backside layer 176 of the substrate 170. In accordance with one embodiment, the transistors 702A-702H may be implemented as an array thereof. In accordance with one embodiment, the transistors 702A-702H may be implemented as TFT FinFET transistors, or the like. Formation of the transistors 702A-702H is described in greater detail above with respect to FIGS. 3A-3I.

At least one of the source or drain of the planar transistors 702A-702H are electrically connected to suitable metal-insulator-metal (MiM) components 706A-706H, respectively, which are respectively coupled first vias 708A-708H. It will be appreciated that the combination of a planar transistor 702A-702H and MiM component 706A-706H correspond to a 1T1C component, i.e., a one-transistor, one-capacitor component. The backside 114 of the first ASIC wafer component 104 shown in FIG. 10 further includes one or more top metal layer components 226A, 226B, 226C, 226D, 226E, and 226F, disposed in the backside dielectric layer 180. In the embodiment shown in FIG. 10, the top metal layer components 226A-226F are electrically connected to the first vias 708A-708H. It will be appreciated that such first vias 708A-708H may be fabricated of suitable conductive materials including, for example and without limitation, copper, copper-alloy, aluminum, aluminum-alloy, and the like.

As illustrated in FIG. 10, redistribution layer (RDL) components 230A, 230B, 230C, 230D, 230E, and 230F are electrically connected to respective top metal components 226A, 226B, 226C, 226D, 226E, and 226F. As shown in FIG. 10, the RDL components 230A-230F extend through the backside anchor layer 186. Further, one or more anchor pads 232 are positioned in or on the backside anchor layer 186.

The CIS device wafer stack 1000 illustrated in FIG. 10 further includes a third wafer component, i.e., the second ASIC wafer component 106, bonded to the backside anchor layer 186, as shown. In accordance with one embodiment, the second ASIC wafer component 106 depicted in FIG. 10 includes a second ASIC wafer substrate 234 comprising one or more layers. The second ASIC wafer component 106 further includes a second ASIC dielectric layer 236 formed on the substrate 234. The second ASIC wafer component 106 may further include a second ASIC anchor layer 238 formed on the second ASIC dielectric layer 236. The aforementioned anchor layer 238 may be implemented as a suitable dielectric material including, for example and without limitation SiN, oxide, SiOₓF_{y}C_{z}Nₐ, polymer, resin, low-K material, high-K material, or any related insulation layers, or the like.

In FIG. 10, the second ASIC dielectric layer 236 of the second ASIC wafer component 106 includes one or more first metal layer components 240A, 240B, and 240C. The second ASIC wafer component 106 further includes one or more second metal layer components 242A, 242B, and 242C, disposed in the dielectric layer 236, and electrically connected to respective first metal layer components 240A, 240B, and 240C, by first vias 244A, 244B, and 244C. It will be appreciated that such first vias 244A-244D may be fabricated of suitable conductive materials including, for example and without limitation, copper, copper-alloy, aluminum, aluminum-alloy, and the like.

The second ASIC wafer component 106 further includes one or more third metal layer components 246A, 246B, and 246C disposed in the dielectric layer 236 and electrically connected to respective one or more second metal layer components 242A, 242B, 242C by respective second vias 248A, 248B, and 248C. It will be appreciated that such second vias 248A-248C may be fabricated of suitable conductive materials including, for example and without limitation, copper, copper-alloy, aluminum, aluminum-alloy, and the like.

The second ASIC wafer component 106 depicted in FIG. 10, further includes one or more top metal layer components 250A, 250B, and 250C. The one or more third metal layer components 246A, 246B, and 246C are electrically connected to respective top metal layer components 250A, 250B, and 250C by respective third vias 252A, 252B, and 252C. It will be appreciated that such third vias 252A-252C may be fabricated of suitable conductive materials including, for example and without limitation, copper, copper-alloy, aluminum, aluminum-alloy, and the like. In some embodiments, the aforementioned metal layer components 240A-240C, 242A-242C, and 246A-246C may be fabricated of copper, copper alloys, aluminum, aluminum-alloy, or other conductive material.

The second ASIC wafer component 106 illustrated in FIG. 10 further includes one or more planar transistors 704A, 704B, and 704C, positioned on or adjacent to respective first metal layer components 240A, 240B, and 240C. At least one of the source or drain of the planar transistors 704A-704C are electrically connected to suitable metal-insulator-metal (MiM) components 254A-254C, respectively, which are respectively coupled fourth vias 256A-256C. Formation of the transistors 704A-704C is described in greater detail above with respect to FIGS. 3A-3I. It will be appreciated that the combination of a planar transistor 704A-704C and MiM component 254A-254C correspond to a 1T1C component, i.e., a one-transistor, one-capacitor component. As shown in FIG. 10, the 1T1C components, i.e., combination transistor (704A-704C) with corresponding capacitor (MiM component 254A-254C), are positioned between the respective first metal layer components 240A-240C and top metal layer components 250A-250C. Accordingly, fourth vias 256A-256C establish electrical connectivity between the top metal layer components 250A-250C and the MiM components 254A-254C as shown.

FIG. 10 further depicts one or more redistribution layer (RDL) components 258A, 258B, 258C 258D, 258E, and 258F electrically connected to top metal components 250A, 250B, and 250C. In some embodiments, the RDL components 258A-258F extend through the second ASIC anchor layer 238, to contact corresponding RDL components 230A-230F of the first ASIC wafer component 106, as shown in FIG. 10. In addition, the second ASIC wafer component 106 includes one or more anchor pads 260 positioned in or on the second ASIC anchor layer 238 configured to contact corresponding anchor pads 232 of the first ASIC wafer component 106. As shown in FIG. 10, the second ASIC wafer component 106 also includes one or more transistor gates or “devices”, i.e., FinFET device, GAA device, HKMG device, SiGe S/D device, SOI device, Poly device, Doped Poly device, etc., comprising a contact 262 coupling a gate component 264 to a first metal layer component 240A-240D, as discussed above with respect to FIG. 1.

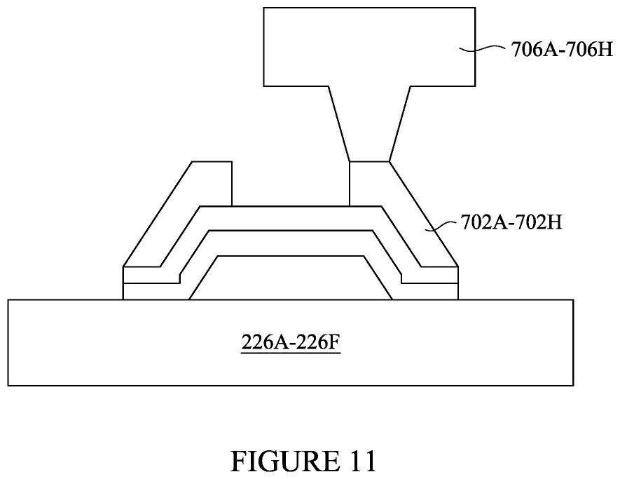

FIG. 11 provides a diagrammatic simplified view of the 1T (one transistor)-1C (MiM) combination of FIG. 10. That is, FIG. 11 depicts a planar transistor 701A-701B, 702A-702H, or 704A-704C having a source/drain contacting a capacitor (MiM component) 142A-142B, 706A-706H, or 254A-254C, respectively.

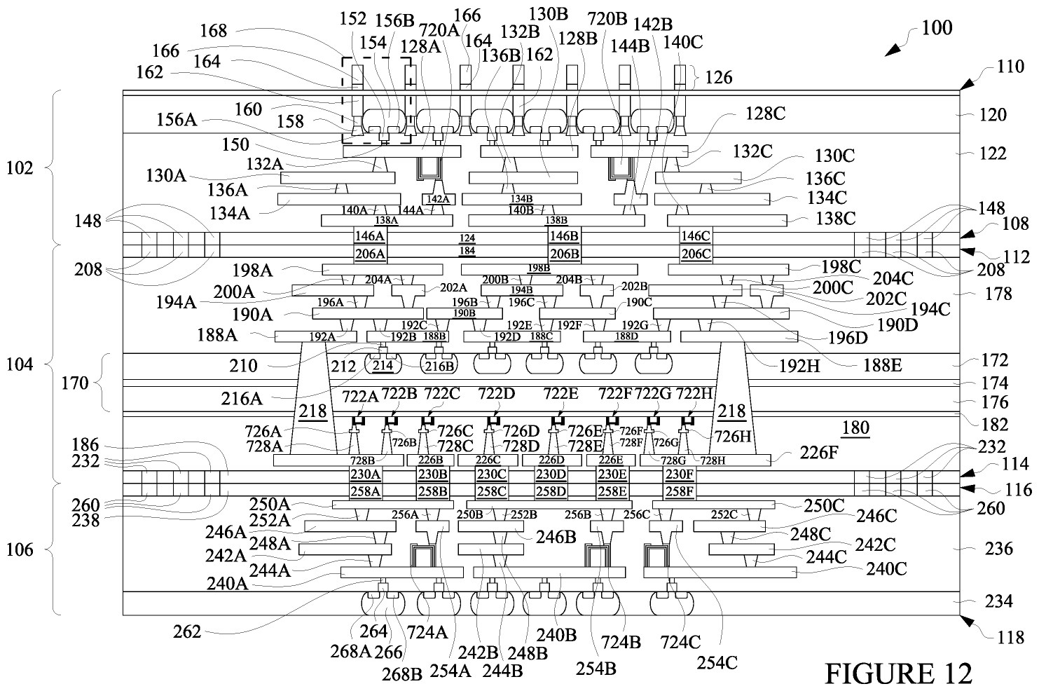

Turning now to FIG. 12, there is shown a CIS device wafer stack 1200 in accordance with a fifth embodiment. That is, FIG. 12 provides a diagrammatic cross-sectional view of a CIS wafer stack 1200 similar to the wafer stack 1000 of FIG. 10. Accordingly, as shown in FIG. 12, the wafer stack 1200 includes the first SOC wafer component 102, the first ASIC wafer component 104, and the second ASIC wafer component 106. As illustrated in FIG. 12, the first SOC wafer component 102, the first ASIC wafer component 104, and the second ASIC wafer component 106, are substantially identical to those illustrated and described above with respect to FIG. 10. Accordingly, the various components described above with respect to the first SOC wafer component 102, the first ASIC wafer component 104, and the second ASIC wafer component 106 apply to FIG. 12, except as noted below.

In FIG. 12, the first SOC wafer component 102 includes all features described above with respect to FIG. 10 except the planar transistors 701A, 701B are replaced with three-dimensional transistors 720A and 720B, respectively. That is, the first SOC wafer component 102 illustrated in FIG. 12 utilizes three-dimensional transistors 720A-720B constructed as discussed above with respect to FIGS. 5A-6B. Accordingly, the planar transistors 701A-701B shown in FIG. 10 have been replaced with three-dimensional transistors 720A and 720B. At least one of the source or drain of the three-dimensional transistors 720A-720B are electrically connected to the metal-insulator-metal (MiM) components 142A and 142B, which are respectively coupled to the top metal layer components 138A and 138B via respective fourth vias 144A and 144B. It will be appreciated that the combination of a three-dimensional transistor 720A-720B and MiM component 142A-142B correspond to a 1T1C component, i.e., a one-transistor, one-capacitor component. The remaining components of the first SOC wafer component 102 in FIG. 12 correspond to those components previously described above with respect to FIG. 10.

The first ASIC wafer component 106 shown in FIG. 12 is similar to the embodiment described above with respect to FIG. 10. However, as illustrated in FIG. 12, the planar transistors 702A-702H located on the oxide layer 182 of the backside 114 of the first ASIC wafer component 104 have been replaced with three-dimensional transistors 722A, 722B, 722C, 722D, 722E, 722F, 722G, and 722H as shown. Accordingly, at least one of the source or drain of the three-dimensional transistors 722A-722F are electrically connected to suitable metal-insulator-metal (MiM) components 726A, 726B, 726C, 726D, 726E, 726F, 726G, and 726H, which are respectively coupled to the top metal layer components 226A, 226B, 226C, 226D, 226E, and 226F by respective first vias 728A, 728B, 728C, 728D, 728E, 728F, 728G, and 728H. Formation of the three-dimensional transistors 722A-722H may be accomplished as described above with respect to FIGS. 5A-6B. It will be appreciated that the combination of a three-dimensional transistor 722A-722H and MiM component 724A-724H correspond to a 1T1C component, i.e., a one-transistor, one-capacitor component. The remaining components of the first ASIC wafer component 104 in FIG. 12 correspond to those components previously described above with respect to FIG. 10.

The second ASIC wafer component 106 of the CIS device wafer stack 1200 depicted in FIG. 12 is similar to the embodiment described above with respect to FIG. 10. In FIG. 12, the planar transistors 704A-704C positioned on or adjacent to respective first metal layer components 240A, 240B, and 240C are replaced with three-dimensional transistors 724A, 724B, and 724C. At least one of the source or drain of the three-dimensional transistors 724A-724C are electrically connected to suitable metal-insulator-metal (MiM) components 254A-254C, respectively, which are respectively coupled fourth vias 256A-256C. Formation of the transistors 724A-724C is described in greater detail above with respect to FIGS. 5A-6B. It will be appreciated that the combination of a three-dimensional transistor 724A-724C and MiM component 254A-254C correspond to a 1T1C component, i.e., a one-transistor, one-capacitor component. As shown in FIG. 12, the 1T1C components, i.e., combination transistor (724A-724C) with corresponding capacitor (MiM component 254A-254C), are positioned between the respective first metal layer components 240A-240C and top metal layer components 250A-250C. Accordingly, fourth vias 256A-256C establish electrical connectivity between the top metal layer components 250A-250C and the MiM components 254A-254C as shown. The remaining components of the second ASIC wafer component 106 in FIG. 12 correspond to those components previously described above with respect to FIG. 10.

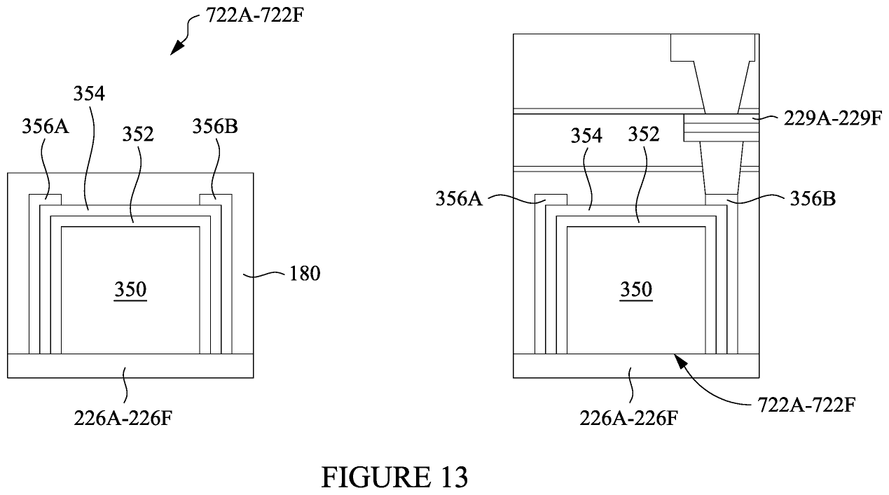

FIG. 13 provides a diagrammatic simplified view of the transistor-MiM combinations of FIG. 12. That is, FIG. 13 depicts a three-dimensional transistor 720A-720B, 722A-722H, or 724A-724C having a source/drain contacting a capacitor (MiM component) 142A-142B, 726A-726H, or 254A-254C, respectively.

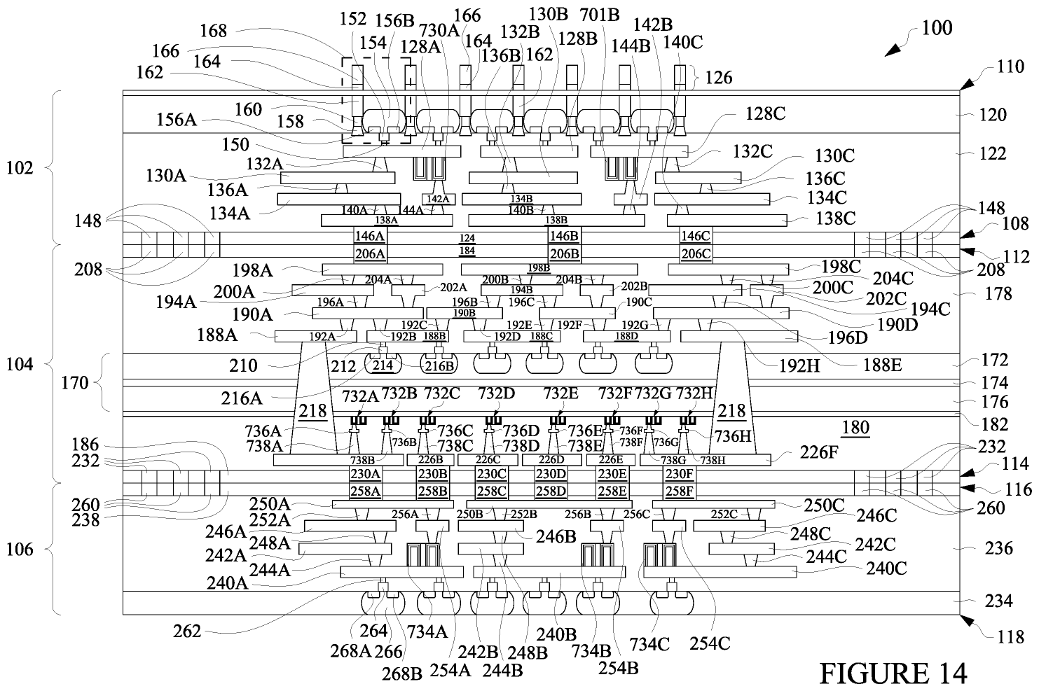

Referring now to FIG. 14, there is shown a CIS device wafer stack 1400 in accordance with a sixth embodiment. That is, FIG. 14 provides a diagrammatic cross-sectional view of a CIS wafer stack 1400 similar to the wafer stack 1000 of FIG. 10 and the wafer stack 1200 of FIG. 12. Accordingly, as shown in FIG. 14, the wafer stack 1400 utilizes a first SOC wafer component 102, a first ASIC wafer component 104, and a second ASIC wafer component 106. As illustrated in FIG. 14, the first SOC wafer component 102, the first ASIC wafer component 104, and the second ASIC wafer component 106, are substantially identical to those illustrated and described above with respect to FIG. 10 and FIG. 12. Accordingly, the various components described above with respect to the first SOC wafer component 102, the first ASIC wafer component 104, and the second ASIC wafer component 106 apply to FIG. 14, except as noted below.

The first SOC wafer component 102 shown in FIG. 14 replaces the planar transistors 701A-701B of FIG. 10 and the three-dimensional transistors 720A-720B of FIG. 12 with a different three-dimensional transistor design, as illustrated in FIG. 14. Thus, the planar transistors 701A, 701B are replaced with three-dimensional transistors 730A and 730B, respectively. That is, the first SOC wafer component 102 illustrated in FIG. 14 utilizes three-dimensional transistors 730A-730B constructed as discussed above with respect to FIGS. 8A-9B. At least one of the source or drain of the three-dimensional transistors 730A-730B are electrically connected to the metal-insulator-metal (MiM) components 142A and 142B, which are respectively coupled to the top metal layer components 138A and 138B via respective fourth vias 144A and 144B. It will be appreciated that the combination of a three-dimensional transistor 730A-730B and MiM component 142A-142B correspond to a 1T1C component, i.e., a one-transistor, one-capacitor component. The remaining components of the first SOC wafer component 102 in FIG. 14 correspond to those components previously described above with respect to FIG. 10.

The first ASIC wafer component 106 shown in FIG. 14 is similar to the embodiment described above with respect to FIG. 10 and FIG. 12. However, as illustrated in FIG. 14, the planar transistors 702A-702H (FIG. 10) and three-dimensional transistors 720A-720H (FIG. 12) located on the oxide layer 182 of the backside 114 of the first ASIC wafer component 104 have been replaced with three-dimensional transistors 732A, 732B, 732C, 732D, 732E, 732F, 732G, and 732H as shown. Accordingly, at least one of the source or drain of the three-dimensional transistors 732A-732F are electrically connected to suitable metal-insulator-metal (MiM) components 736A, 736B, 736C, 736D, 736E, 736F, 736G, and 736H, which are respectively coupled to the top metal layer components 226A, 226B, 226C, 226D, 226E, and 226F by respective first vias 738A, 738B, 738C, 738D, 738E, 738F, 738G, and 738H. Formation of the three-dimensional transistors 732A-732H may be accomplished as described above with respect to FIGS. 8A-9B. It will be appreciated that the combination of a three-dimensional transistor 732A-732H and MiM component 734A-734H correspond to a 1T1C component, i.e., a one-transistor, one-capacitor component. The remaining components of the first ASIC wafer component 104 in FIG. 14 correspond to those components previously described above with respect to FIG. 10 and FIG. 12.

The second ASIC wafer component 106 of the CIS device wafer stack 1400 depicted in FIG. 14 is similar to the embodiment described above with respect to FIG. 10 and FIG. 12. In FIG. 14, the planar transistors 704A-704C (FIG. 10) and the three-dimensional transistors 724A-724C (FIG. 12) positioned on or adjacent to respective first metal layer components 240A, 240B, and 240C are replaced with three-dimensional transistors 734A, 734B, and 734C. At least one of the source or drain of the three-dimensional transistors 724A-724C are electrically connected to suitable metal-insulator-metal (MiM) components 254A-254C, respectively, which are respectively coupled fourth vias 256A-256C. Formation of the transistors 724A-724C is described in greater detail above with respect to FIGS. 8A-9B. It will be appreciated that the combination of a three-dimensional transistor 734A-734C and MiM component 254A-254C correspond to a 1T1C component, i.e., a one-transistor, one-capacitor component. As shown in FIG. 14, the 1T1C components, i.e., combination transistor (734A-734C) with corresponding capacitor (MiM component 254A-254C), are positioned between the respective first metal layer components 240A-240C and top metal layer components 250A-250C. Accordingly, fourth vias 256A-256C establish electrical connectivity between the top metal layer components 250A-250C and the MiM components 254A-254C as shown. The remaining components of the second ASIC wafer component 106 in FIG. 14 correspond to those components previously described above with respect to FIG. 10 and FIG. 12.

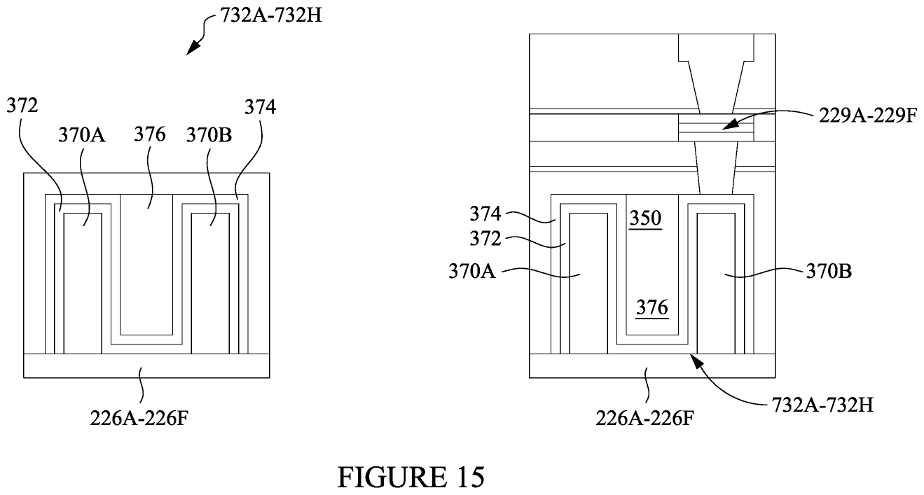

FIG. 15 provides a diagrammatic simplified view of the transistor-MiM combinations of FIG. 14. That is, FIG. 15 depicts a three-dimensional transistor 730A-730B, 732A-732H, or 734A-734C having a source/drain contacting a capacitor (MiM component) 142A-142B, 726A-726H, or 254A-254C, respectively.

In some embodiments, the three-dimensional transistors described herein may be implemented with an IGZO thickness may be in the range of about 1 nm to 12 nm and in some instances 2 nm to 6 nm. In such embodiments, the HfOx and TiN components may have a thickness in the range of about 1 nm to 30 nm and in some instances 5 nm to 15 nm. The length of the IGZO channel (vertically) may be in the range of about 5 nm to 100 nm and in some instances 20 nm to 80 nm. In such embodiments, the critical dimension in-plane may be in the range of about 10 nm to 90 nm and in some instances 25 nm to 75 nm.

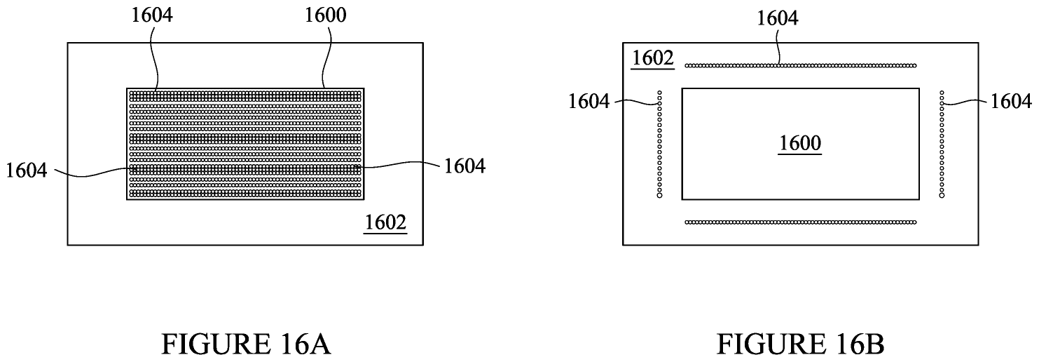

In accordance with some embodiments, different types of hybrid bonding may be utilized herein. In some embodiments, pixel-level hybrid bonding (PLHB) or column-level hybrid bonding (CLHB) may be used. In PLHB, bonding (i.e., RDL to RDL of wafers) occurs underneath the photodiode array. In CLHB, bonding (i.e., RDL to RDL of wafers) occurs below (layer-wise), but outside the photodiode area. FIG. 16A and FIG. 16B provide simplified top views of the wafer stacks 100, 400, 700, 1000, 1200, and 1400 of respective FIGS. 1, 4, 7, 10, 12, and 14. All elements except for the RDL-to-RDL connections (i.e., hybrid bonds) and a general designation for the location of the array of photodiodes 168 has been removed to illustrate positioning of the various RDL components 146A-146C/206A-206C, 230A-230F/258A-258F either directly underneath the photodiodes 168 (PLHB) or around the photodiodes 168 (CLHB).

For example, FIG. 16A provides an illustration of PLHB, wherein the photodiode area 1600 is shown by the box in the center of the image. Surrounding the photodiode area 1600 is a periphery area 1602, wherein no RDL-to-RDL bonding occurs. The hybrid bonds 1604 are denoted by the plurality of circles within the photodiode area 1600. Thus, when viewing FIGS. 1, 4, 7, 10, 12, and 14, the hybrid bonds 1604 correspond to the RDL-to-RDL component bonding between wafer components 102, 104, and 106. In the PLHB of FIG. 16, the hybrid bonds 1604 are therefore positioned directly below the photodiode area 1600. FIG. 16B provides an illustration of a CLHB embodiment, wherein no hybrid bonds 1604 are located in the periphery area 1602, and not underneath the photodiode area 1600.

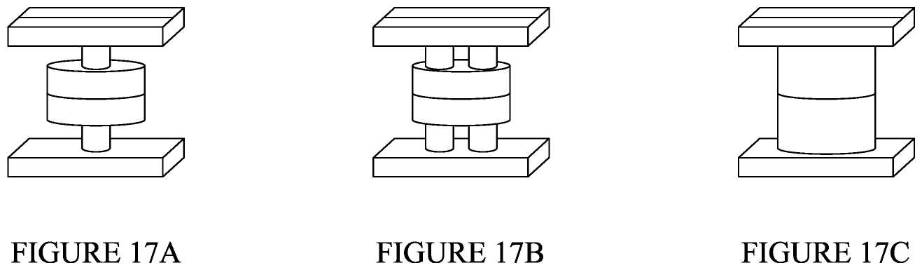

Referring now to FIGS. 17A-17C, there are shown various types of hybrid bonds 1600 capable of being used in one or more embodiments. FIGS. 17A and 17B illustrate a type 1 hybrid bond, utilizing a single thin column of RDL materials (FIG. 17A) or utilizing two thin columns of RDL materials (FIG. 17B). FIG. 17C provide an illustration of a type 2 hybrid bond, wherein a single, substantially larger column of RDL material is used for forming the hybrid bonds 1604 depicted in FIGS. 16A-16B. In accordance with some embodiments, CLHB bonding utilizes a type 2 hybrid bond. In other embodiments, PLHB bonding may utilize either type 1 hybrid bond, and/or type 2 hybrid bond.

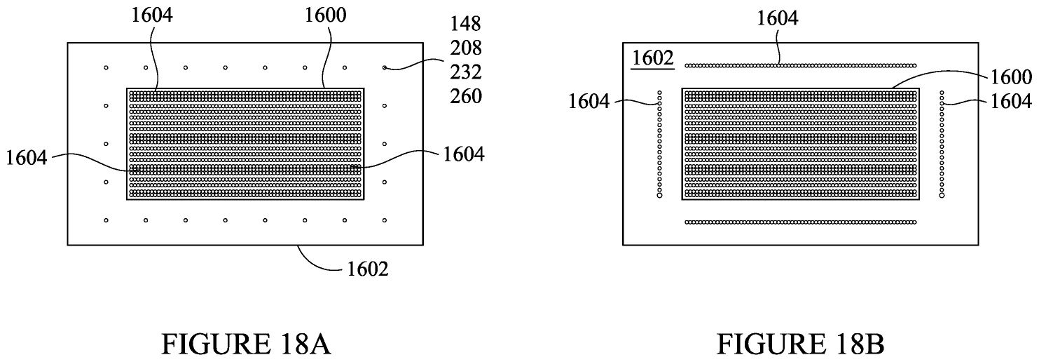

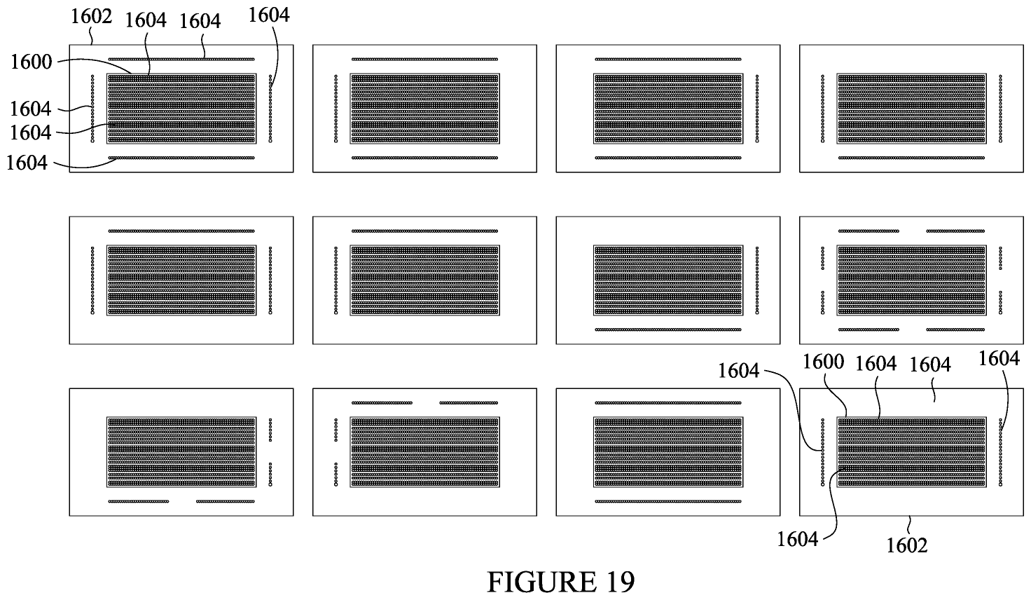

As discussed above, the wafer stack 100, 400, 700, 1000, 1200, and/or 1400 may use one or more anchor pads 148, 208, 232, 260 to facilitate bonding of wafer components 102-106. Such anchor pads 148, 208, 232, 260 may be used in PLHB bonding, as illustrated in FIG. 18A. In some embodiments, such as shown in FIG. 18B, PLHB bonding may use type 2 hybrid bonding formations. It will be appreciated that in such an embodiment, i.e., FIG. 18B, replacement of anchor pads 148, 208, 232, 260 with hybrid bonding connections of type 2 reduces manufacturing costs and times, as the type 2 hybrid bond is generally stronger than that of type 1, the materials used for such bond are being deposited already for RDL components 146A-146C/206A-206C, 230A-230F/258A-258F, and no additional metal depositions are required as anchor pads. In accordance with use of the type 2 connection of FIG. 17C, PLHB and CLHB implementations of the wafer stacks 100, 400, 700, 1000, 1200, and 1400 may utilize any variation of rows and/or columns of hybrid bonds 1604 in the periphery area 1602, as illustrated in the various configurations depicted in FIG. 19.

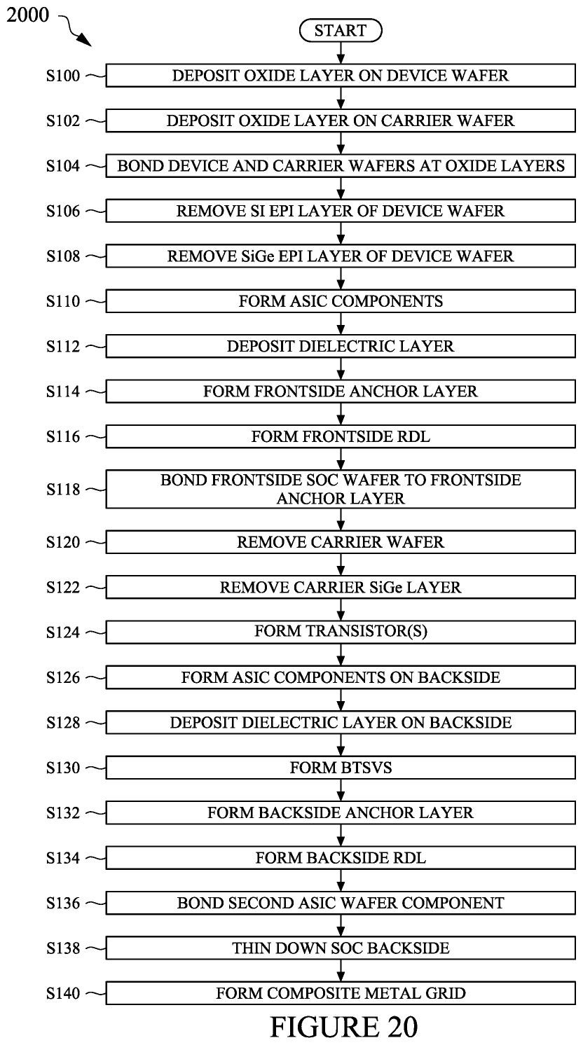

Turning now to FIG. 20, there is shown a flowchart 2000 illustrating a method for forming a CIS device wafer stack 100 in accordance with some embodiments. The method begins at S100, whereupon an oxide layer SiO2 layer 316 is deposited on a device wafer 300. Device wafer 300 includes a device wafer substrate 304, upon which are formed a device wafer SiGe EPI layer 306 and a Si EPI layer 308. At S102, an oxide layer SiO2 layer 318 is deposited on a carrier wafer 302. The carrier wafer 302 shown in FIG. 2A includes a carrier wafer substrate 310 upon which are formed a carrier wafer SiGe EPI layer 312 and a carrier wafer Si EPI layer 314. At S104, the device wafer 300 is bonded to the carrier wafer 302. That is, an oxide-oxide bond is formed between the device wafer 300 and the carrier wafer 302.

At S106, the Si EPI layer 308 of the device wafer 300 is removed via etching or other suitable mechanism. At S108, the SiGe EPI layer 306 is removed via etching or other suitable mechanism. At S110, ASIC components, i.e., metal layer components, are formed on the device carrier 300, as shown in FIG. 2F. In some embodiments, the ASIC formation corresponds to FEOL, BEOL, etc., as shown.

At S112, a dielectric layer 178 is then deposited. At S114, a frontside anchor layer 184 is formed on the dielectric layer 178. At S116, frontside redistribution layer components 206A-206C are formed. At S118, the intermediate device (as illustrated in FIG. 2F) is then inverted and hybrid bonded (e.g., a combination of oxide-oxide and metal-metal bonding) to the SOC wafer component 102. At S120, the carrier wafer substrate 310 is removed, i.e., etched, using the carrier wafer SiGe EPI layer 312 as an etch stop layer. At S122, the SiGe EPI layer 312 is then removed via etching or other suitable mechanism, as shown in FIG. 2I. At S124, a low temperature IGZO transistor array 220A-220F is formed on an oxide layer 182. At S126, one or more ASIC components are formed on the backside 114, e.g., metal layer components 222A-222F, 226A-226F. At S128, a dielectric layer 180 is deposited on the backside 114 of the first ASIC wafer component 104. One or more BTSVs 218 are then formed at S130, electrically coupling the frontside 112 of the first ASIC wafer component 104 with the backside 114.

At S132, a backside anchor layer 186 is formed on the dielectric layer 180. One or more backside redistribution layer components 230A-230F are then formed through the anchor layer 186 and dielectric layer 180 at S134. At S136, the second ASIC wafer component 106 is then bonded to the backside 114 of the first ASIC wafer component 104. The backside 110 of the SOC wafer component 102, i.e., the SOC substrate 120, is then thinned down at S138. In some embodiments, CMP or other mechanical or chemical methodologies are used to thin the SOC substrate 120. At S140, the composite metal grid and remaining photodiode components are formed.

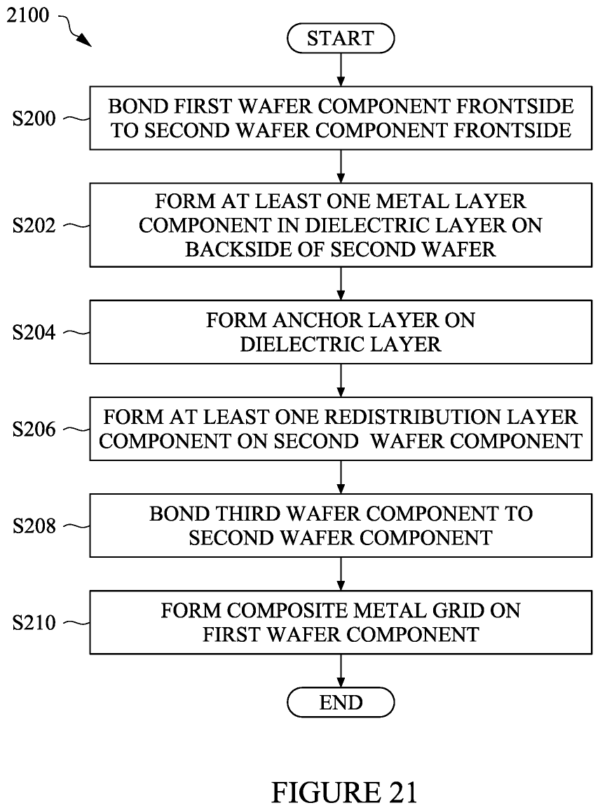

Turning now to FIG. 21, there is shown a flowchart 2100 illustrating a method for forming a wafer stack in accordance with another embodiment. The method begins at S200, whereupon a frontside 108 of a first wafer component 102 is bonded to a frontside 112 of a second wafer component 104. At S202, one or more metal layer components 226A-226F, 222A-222F are formed in a dielectric layer 180 of the second wafer component 104. An anchor layer 186 is then formed, at S204, on the dielectric layer 180. At S206, one or more redistribution layer components 230A-230F are formed on the metal layer components 226A-226F, which extend through the dielectric layer 180 and anchor layer 186.

At S208, a third wafer component 106 is bonded to the second wafer component 104. In some embodiments, the third wafer component 106 includes an anchor layer 238 and redistribution layer components 258A-258F. Further, bonding of the second wafer component 104 and the third wafer component 106 corresponds to bonding of the redistribution layer component 230A-230F to the redistribution layer components 258A-258F. At S210, a composite metal grid 126 is formed on a backside 110 of the first wafer component 102.

In some embodiments, use of the three-dimensional 1T1C components may enhance SOI backside power drive, as the backside transistor array have low current usage. In other embodiments, use of the three-dimensional 1T1C components described above may provide backend bias and current drive. Accordingly, the three-dimensional 1T1C components described herein may function as DRAM, FeRAM, RRAM, and the like.

In accordance with a first embodiment, there is provided a method of forming a wafer stack. The method includes bonding the frontside of a first wafer component to the frontside of a second wafer component. The method further includes forming one or more metal components in a dielectric layer on the backside of the second wafer component, and forming an anchor layer on the dielectric layer on the backside of the second wafer component. In addition, the method includes forming one or more redistribution layer components on the metal layer components, such that the redistribution layer components extend through the dielectric layer and the anchor layer. The method further includes bonding a third wafer component to the second wafer component. In such an embodiment, the third wafer component includes an anchor layer and one or more redistribution layer components that extend through the anchor layer. Further, the bonding of the third wafer component to the second wafer component corresponds to bonding of the second wafer component redistribution layer components to the third wafer component redistribution layer components.

In accordance with a second embodiment, there is provided wafer stack that includes a first wafer component that has a frontside and a backside. The wafer stack also includes a second wafer component having a frontside and a backside, such that the frontside of the second wafer component is bonded to the frontside of the first wafer component. In addition, the wafer stack includes a third wafer component having a frontside and a backside, such that the frontside of the third wafer component is bonded to the backside of the second wafer component.

In accordance with a third embodiment, there is provided a method of forming a wafer stack. The method includes forming a first ASIC wafer component by forming one or more metal layer components on a first ASIC wafer substrate that has a frontside layer and a backside layer positioned between the frontside and the backside of the first ASIC wafer component, such that the one or more metal components are formed on the frontside of the first ASIC wafer substrate. Forming the first ASIC wafer component also includes depositing a frontside dielectric layer on the substrate, forming a frontside anchor layer on the frontside dielectric layer, and forming one or more redistribution layer components that contact the metal layer components and extend through the frontside anchor layer. The method of forming a wafer stack further includes bonding a frontside of a system on chip wafer component to the anchor layer of the first ASIC wafer component, and forming one or more metal layer components on the backside layer of the first ASIC wafer substrate after bonding with the system on chip wafer component. The method further includes depositing a backside dielectric layer on the first ASIC wafer substrate, and forming a backside anchor layer on the backside dielectric layer. In addition, the method of forming a wafer stack includes forming one or more redistribution layer components that contact the metal layer components and extend through the backside anchor layer. Further, the method includes bonding a frontside of a second ASIC wafer component to the backside anchor layer of the first ASIC wafer component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a wafer stack, comprising:
bonding a frontside of a first wafer component to a frontside of a second wafer component;
forming at least one metal component in a dielectric layer on a backside of the second wafer component;
forming an anchor layer on the dielectric layer on the backside of the second wafer component;
forming at least one redistribution layer component on the at least one metal layer component, wherein the at least one redistribution layer component extending through the dielectric layer and the anchor layer; and
bonding a third wafer component to the second wafer component,
wherein the third wafer component includes an anchor layer and at least one redistribution layer component extending therethrough, and
wherein the bonding of the third wafer component to the second wafer component corresponds to a bonding of the at least one second wafer component redistribution layer component to the at least one third wafer component redistribution layer component.

2. The method of claim 1, wherein the first wafer component is a system on chip wafer component, and the second wafer component and third wafer component are an ASIC wafer component.

3. The method of claim 1, further comprising:
forming at least one transistor on the backside of the second wafer component, wherein the at least one transistor is contacting the at least one metal component.

4. The method of claim 3, further comprising:
forming at least one metal-insulator-metal component contacting the at least one transistor.

5. The method of claim 4, wherein the at least one transistor is a three-dimensional transistor or a planar transistor.

6. The method of claim 3, further comprising forming the second wafer component, including:
depositing a dielectric layer on a device wafer, the device wafer comprising a substrate, a first EPI layer and a second EPI layer, wherein the dielectric layer is deposited on the second EPI layer;
depositing a dielectric layer on a carrier wafer, the carrier wafer comprising a substrate, a first EPI layer and a second EPI layer, wherein the dielectric layer is deposited on the second EPI layer;
bonding the dielectric layer of the device wafer to the dielectric layer of the carrier wafer;
removing the substrate of the device wafer;
removing the first etch stop layer of the device wafer;
forming at least one metal layer component in a dielectric layer on the second EPI layer of the device wafer;
forming an anchor layer on the dielectric layer;
forming at least one redistribution layer component extending through the anchor layer to the at least one metal layer component disposed in the dielectric layer.

7. The method of claim 3, wherein the first wafer component comprises:
a substrate having a frontside surface and backside surface;
a dielectric layer on the front side surface;
at least one metal layer component disposed in the dielectric layer;
an anchor layer formed on the dielectric layer; and
at least one redistribution layer component extending through the anchor layer to the at least one metal layer component disposed in the dielectric layer,
wherein the at least one redistribution layer component of the first wafer component is bonded to the at least one redistribution layer component of the second wafer component forming a first hybrid bond therebetween.

8. A wafer stack, comprising:
a first wafer component having a frontside and a backside,
a second wafer component having a frontside and a backside, wherein the frontside of the second wafer component is bonded to the frontside of the first wafer component; and
a third wafer component having a frontside and a backside, wherein the frontside of the third wafer component is bonded to the backside of the second wafer component.

9. The wafer stack of claim 8, wherein the first wafer component is a system on chip, and wherein at least one photodiode is formed on the backside of the first wafer component.

10. The wafer stack of claim 9, wherein the second wafer component comprises:
a substrate having a frontside layer and a backside layer positioned between the frontside and the backside thereof;
a frontside dielectric layer disposed on the substrate, wherein at least one metal layer component is disposed therein;
a backside dielectric layer disposed on the substrate, wherein at least one metal layer component is disposed therein;
at least one via contacting the at least one frontside metal layer component and the at least one backside metal layer component through the substrate; and
at least one transistor positioned on the backside layer of the substrate and contacting the at least one metal layer component disposed in the backside dielectric layer.

11. The wafer stack of claim 10, further comprising at least one metal-insulator-metal component electrically contacting the at least one transistor.

12. The wafer stack of claim 11, wherein the at least one transistor is a three-dimensional transistor or a planar transistor.

13. The wafer stack of claim 12, wherein the first wafer component further comprises:
a substrate having a frontside surface and backside surface;
a dielectric layer on the front side surface;
at least one metal layer component disposed in the dielectric layer;
an anchor layer formed on the dielectric layer; and
at least one redistribution layer component extending through the anchor layer to the at least one metal layer component disposed in the dielectric layer.

14. The wafer stack of claim 13, wherein the first wafer component further comprises:
at least one transistor positioned on the at least one metal layer component, and
at least one metal-insulator-metal component electrically contacting the at least one transistor,
wherein the at least one transistor is a three-dimensional transistor or a planar transistor.

15. The wafer stack of claim 13, wherein the third wafer component further comprises:
a substrate having a frontside surface and backside surface;
a dielectric layer on the front side surface;
at least one metal layer component disposed in the dielectric layer;
an anchor layer formed on the dielectric layer; and
at least one redistribution layer component extending through the anchor layer to the at least one metal layer component disposed in the dielectric layer.

16. The wafer stack of claim 15, wherein the third wafer component further comprises:
at least one transistor positioned on the at least one metal layer component, and
at least one metal-insulator-metal component electrically contacting the at least one transistor,
wherein the at least one transistor is a three-dimensional transistor or a planar transistor.

17. The wafer stack of claim 15, wherein the second wafer component further comprises:
a frontside anchor layer formed on the frontside dielectric layer;
a backside anchor layer formed on the backside dielectric layer;
at least one frontside redistribution layer component extending through the frontside anchor layer to the at least one metal layer component disposed in the frontside dielectric layer; and
at least one backside redistribution layer component extending through the backside anchor layer to the at least one metal layer component disposed in the backside dielectric layer.

18. The wafer stack of claim 15, wherein:
the at least one redistribution layer component of the first wafer component is bonded to the at least one frontside redistribution layer component of the second wafer component forming a first hybrid bond therebetween; and
the at least one redistribution layer component of the third wafer component is bonded to the at least one backside redistribution layer component of the second wafer component forming a second hybrid bond therebetween.

19. A method of forming a wafer stack, comprising:
forming a first ASIC wafer component comprising:
forming at least one metal layer component on a first ASIC wafer substrate having a frontside layer and a backside layer positioned between a frontside of the first ASIC wafer component and a backside of the first ASIC wafer component, wherein the at least one metal component is formed on the frontside of the first ASIC wafer substrate,
depositing a frontside dielectric layer on the substrate,
forming a frontside anchor layer on the frontside dielectric layer, and
forming at least one redistribution layer component contacting the at least one metal layer component and extending through the frontside anchor layer;
bonding a frontside of a system on chip wafer component to the anchor layer of the first ASIC wafer component;
forming at least one metal layer component on the backside layer of the first ASIC wafer substrate subsequent to bonding with the system on chip wafer component;
depositing a backside dielectric layer on the first ASIC wafer substrate;
forming a backside anchor layer on the backside dielectric layer,
forming at least one redistribution layer component contacting the at least one metal layer component and extending through the backside anchor layer; and
bonding a frontside of a second ASIC wafer component to the backside anchor layer of the first ASIC wafer component.

20. The method of claim 19, wherein
the frontside of the system on chip wafer component further comprises a system on chip anchor layer and at least one redistribution layer component extending therethrough;
the frontside of the second ASIC wafer component further comprises a second ASIC wafer component anchor layer and at least one redistribution layer component extending therethrough;
the at least one redistribution layer component of the system on chip wafer component is bonded to the at least one frontside redistribution layer component of the first ASIC wafer component forming a first hybrid bond therebetween; and
the at least one redistribution layer component of the second ASIC wafer component is bonded to the at least one backside redistribution layer component of the second wafer component forming a second hybrid bond therebetween.
